(19) United States
(12) Patent Application Publication
(10) Pub. No.: US 2025/0178313 A1
(43) Pub. Date: Jun. 5, 2025

(54) LAMINATE, FILM, THERMOSETTING FILM, AND MANUFACTURING METHOD OF WIRING BOARD

(71) Applicant: FUJIFILM Corporation, Tokyo (JP)

(72) Inventors: Daisuke HAYASHI, Kanagawa (JP); Keita TAKAHASHI, Kanagawa (JP)

(73) Assignee: FUJIFILM Corporation, Tokyo (JP)

(21) Appl. No.: 19/053,366

(22) Filed: Feb. 13, 2025

Related U.S. Application Data
(63) Continuation of application No. PCT/JP2023/031833, filed on Aug. 31, 2023.

(30) Foreign Application Priority Data
Aug. 31, 2022 (JP) 2022-138486

(51) Int. Cl. B32B 15/088; B32B 15/06; B32B 15/20; B32B 37/06; H05K 3/28

(52) U.S. Cl. CPC B32B 15/088; B32B 15/06; B32B 15/20; B32B 37/06; H05K 3/285; B32B 2274/00; B32B 2305/30; B32B 2305/55; B32B 2307/202; B32B 2307/51; B32B 2377/00; B32B 2457/08; H05K 2203/1194; H05K 2203/1377

(57) ABSTRACT

Provided are: a laminate including a layer A, a layer B on at least one surface of the layer A, and a conductive pattern in contact with at least a part of the layer B, in which the laminate has a dielectric loss tangent of 0.01 or less at 28 GHz, and a value obtained by subtracting a mass residual rate at 900° C. from a mass residual rate at 440° C. of the layer B is 40% by mass or more; a film including a layer A and a layer B on at least one surface of the layer A, in which the film has a dielectric loss tangent of 0.01 or less at 28 GHz, an elastic modulus of the layer B is 0.5 MPa or less at 160° C., and the layer B contains a thermosetting resin; a thermosetting film; and a method of manufacturing a wiring board using the film and the thermosetting film.

### CROSS-REFERENCE TO RELATED APPLICATION

This application is a Continuation of International Application No. PCT/JP2023/031833, filed Aug. 31, 2023, which claims priority to Japanese Patent Application No. 2022-138486, filed Aug. 31, 2022. Each of the above applications is hereby expressly incorporated by reference, in its entirety, into the present application.

### BACKGROUND OF THE INVENTION

### 1. Field of the Invention

The present disclosure relates to a laminate, a film, a thermosetting film, and a manufacturing method of a wiring board.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent.

In the related art, polyimide is commonly used as the insulating material used in the circuit board, a liquid crystal polymer which has high heat resistance and low water absorption and is small in loss in the high frequency band has been attracted. In addition, in recent years, with the improvement of the performance of communication equipment, the size of blind vias and through-hole vias processed by multilayering or an ultraviolet (UV) laser has been reduced. Therefore, the layer for following and adhering to the circuit board is required to have excellent low dielectric characteristics and excellent UV laser workability.

As a resin composition for following and adhering to a circuit board in the related art, for example, JP2019-199612A discloses a resin composition including a styrene-based polymer, an inorganic filler, and a curing agent, in which the styrene-based polymer is an acid-modified styrene-based polymer having a carboxyl group, the inorganic filler is silica and/or aluminum hydroxide, a particle diameter of the inorganic filler is 1 μm or less, a content of the inorganic filler is 20 to 80 parts by mass with respect to 100 parts by mass of the styrene-based polymer, and the resin composition satisfies Expression (A) and Expression (B) in a form of a film having a thickness of 25 μm.

X≤50 (A)

Y≥40 (B)

(In the expression, X represents an absorbance (unit: %) of light having a wavelength of 355 nm, and Y represents a haze value (unit: %).)

In addition, JP2022-17947A discloses a thermosetting adhesive sheet including a binder resin and a curing agent, in which a cured product obtained by heating the thermosetting adhesive sheet at 180° C. for 1 hour satisfies (i) to (iv).
(i) In a case where the thickness of the cured product is 25 μm, the energy ray transmittance at a wavelength of 355 nm is 0% to 40%.
(ii) The relative permittivity is 1.5 to 3.0 at a frequency of 10 GHz and 23° C.
(iii) The dielectric loss tangent is 0.0001 to 0.01 at a frequency of 10 GHz and 23° C.
(iv) The linear expansion coefficient al at 0° C. to the glass transition temperature is 100 to 500 ppm/° C.

### SUMMARY OF THE INVENTION

An object to be achieved by an embodiment of the present invention is to provide a laminate having excellent level difference followability and laser processing suitability.

In addition, an object to be achieved by another embodiment of the present invention is to provide a film and a thermosetting film having excellent level difference followability and laser processing suitability, and a manufacturing method of a wiring board using the film or the thermosetting film.

The means for achieving the above-described objects include the following aspects.
<1> A laminate including: a layer A; a layer B on at least one surface of the layer A; and a conductive pattern in contact with at least a part of the layer B, in which the laminate has a dielectric loss tangent of 0.01 or less at 28 GHz, and a value obtained by subtracting a mass residual rate of the layer B at 900° C. from a mass residual rate of the layer B at 440° C. is 40% by mass or more.
<2> The laminate according to <1>, in which the layer B contains a resin having at least one group selected from the group consisting of a maleimide group, an allyl group, and a vinyl group.
<3> The laminate according to <1> or <2>, in which the layer B contains a thermoplastic elastomer.
<4> The laminate according to any one of <1> to <3>, in which the layer B contains an inorganic filler.
<5> The laminate according to any one of <1> to <4>, in which the layer A contains a liquid crystal polymer.
<6> The laminate according to any one of <1> to <5>, in which the layer A contains an aromatic polyester amide.
<7> A film including: a layer A; and a layer B on at least one surface of the layer A, in which the film has a dielectric loss tangent of 0.01 or less at 28 GHz, an elastic modulus of the layer B of 0.5 MPa or less at 160° C., and the layer B contains a thermosetting resin.
<8> The film according to <7>, in which the thermosetting resin has at least one group selected from the group consisting of a maleimide group, an allyl group, and a vinyl group.
<9> The film according to <7> or <8>, in which the layer B further contains a thermoplastic elastomer.
<10> The film according to any one of <7> to <9>, in which the layer B contains an inorganic filler.
<11> The film according to any one of <7> to <10>, in which the layer A contains a liquid crystal polymer.
<12> The film according to any one of <7> to <11>, in which the layer A contains an aromatic polyester amide.
<13> A method of manufacturing a wiring board, the method including: overlaying the film according to any one of <7> to <12> on a wiring pattern of a base material with a wiring pattern from a side of the layer B; and heating the base material with a wiring pattern and the film in a state of being overlaid to obtain a wiring board.
<14> The method of manufacturing a wiring board according to <13>, in which a heating temperature in the heating is 240° C. or lower.
<15> The method of manufacturing a wiring board according to <13> or <14>, in which a value obtained by subtracting a mass residual rate of the layer B at 900° C. from a mass residual rate of the layer B at 440° C. after the heating is 40% or more.
<16> A thermosetting film including: a thermosetting compound; and a thermoplastic elastomer, in which the thermosetting compound has at least one group selected from the group consisting of a maleimide group, an allyl group, and a vinyl group.
<17> The thermosetting film according to <16>, in which the thermosetting film has an elastic modulus of 0.5 MPa or less at 160° C.
<18> The thermosetting film according to <16> or <17>, in which the thermosetting film has a dielectric loss tangent of 0.01 or less at 28 GHz.
<19> The thermosetting film according to any one of <16> to <18>, further including: at least one selected from the group consisting of a polyimide, a liquid crystal polymer, a fluorine-based polymer, and an inorganic filler.
<20> The thermosetting film according to any one of <16> to <19>, further including: an aromatic polyester amide.
<21> A method of manufacturing a wiring board, the method including: overlaying the thermosetting film according to any one of <16> to <20> on a wiring pattern of a base material with a wiring pattern; and heating the base material with the wiring pattern and the thermosetting film in a state of being overlaid to obtain a wiring board.
<22> The method of manufacturing a wiring board according to <21>, in which a heating temperature in the heating is 240° C. or lower.
<23> The method of manufacturing a wiring board according to <21> or <22>, in which a value obtained by subtracting a mass residual rate of the thermosetting film at 900° C. from a mass residual rate of the thermosetting film at 440° C. after the heating step is 40% or more.

According to an embodiment of the present invention, it is possible to provide a laminate having excellent level difference followability and laser processing suitability.

In addition, according to another embodiment of the present invention, it is possible to provide a film and a thermosetting film having excellent level difference followability and laser processing suitability, and a manufacturing method of a wiring board using the film or the thermosetting film.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

Further, in the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit value or a lower limit value in another numerical range described in a stepwise manner. Further, in a numerical range described in the present disclosure, an upper limit value or a lower limit value described in the numerical range may be replaced with a value described in an example.

Further, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth) acryloyl” includes both acryloyl and methacryloyl.

Further, the term “step” in the present specification indicates not only an independent step but also a step which cannot be clearly distinguished from other steps as long as the intended purpose of the step is achieved. Further, in the present disclosure, “% by mass” has the same definition as that for “% by weight”, and “part by mass” has the same definition as that for “part by weight”.

Furthermore, in the present disclosure, a combination of two or more preferred embodiments is a more preferred embodiment.

Further, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

Hereinafter, the present disclosure will be described in detail.

### Laminate

The laminate according to the embodiment of the present disclosure includes a layer A, a layer B on at least one surface of the layer A, and a conductive pattern in contact with at least a part of the layer B, in which a dielectric loss tangent at 28 GHz is 0.01 or less, and a value obtained by subtracting a mass residual rate at 900° C. from a mass residual rate at 440° C. of the layer B is 40% by mass or more.

The present inventors have found that it is difficult to achieve both the level difference followability and the laser processing suitability in the film and the laminate in the related art.

For example, the present inventors have found that in a film of the related art provided with a layer with a low elastic modulus, there is a problem in that the layer with a low elastic modulus is excessively cut in a case where laser processing is performed.

In the laminate according to the embodiment of the present disclosure, the dielectric loss tangent at 28 GHz is 0.01 or less, and the value obtained by subtracting the mass residual rate at 900° C. from the mass residual rate at 440° C. of the layer B is 40% by mass or more, whereby it is possible to provide a laminate having excellent level difference followability and excellent heat resistance of the layer B, and thus having both excellent level difference followability and excellent laser processing suitability.

### Dielectric Loss Tangent of Laminate

The dielectric loss tangent of the laminate according to the embodiment of the present disclosure at 28 GHz is 0.01 or less, and from the viewpoint of dielectric constant, laser processing suitability, and level difference followability, it is preferably 0.008 or less, more preferably 0.005 or less, still more preferably 0.004 or less, and particularly preferably more than 0 and 0.003 or less.

The dielectric loss tangent in the present disclosure is measured by the following method.

The dielectric loss tangent is measured by a resonance perturbation method at a frequency of 28 GHz. A 28 GHz cavity resonator (CP531 manufactured by KANTO Electronic Application and Development Inc.) is connected to a network analyzer (“E8363B” manufactured by Agilent Technology Co., Ltd.), a test piece is inserted into the cavity resonator, and the dielectric loss tangent of the film is measured from change in resonance frequency before and after insertion for 96 hours under an environment of a temperature of 25° C. and humidity of 60% RH.

In a case where each layer is measured, an unnecessary layer may be scraped off with a razor or the like to produce an evaluation sample of only the target layer. In addition, in a case where it is difficult to take out the single film because the thickness of the layer is thin, a layer to be measured may be scraped off with a razor or the like, and the obtained powdery sample may be used. In the present disclosure, the measurement of the dielectric loss tangent of the polymer is carried out according to the above-described measuring method of a dielectric loss tangent by identifying or isolating a chemical structure of the polymer constituting each layer and using a powdered sample of the polymer to be measured.

In addition, in a case of a laminate consisting of a layer A and a layer B, the dielectric loss tangent of the laminate may be obtained by a weighted average of the dielectric loss tangents of the layer A and the layer B and the film thickness.

### Mass Residual Rate

In the laminate according to the embodiment of the present disclosure, a value obtained by subtracting the mass residual rate of the above-described layer B at 900° C. from the mass residual rate of the above-described layer B at 440° C. is 40% or more, and from the viewpoint of laser processing suitability and level difference followability, the value is preferably 40% to 95% and more preferably 45% to 90%.

A value obtained by subtracting the mass residual rate at 900° C. from the mass residual rate at 440° C. of the above-described layer B can be adjusted by the amount of the thermosetting compound, the amount of the inorganic filler, and the like, which will be described later.

The measuring method of the value obtained by subtracting the mass residual rate at 900° C. from the mass residual rate at 440° C. of the layer B in the present disclosure is as follows.

The layer B is cut from the film, 5 mg thereof is added to a platinum pan, and the measurement is performed at a temperature rising rate of 10° C./min and a measurement temperature of 25° C. to 900° C. using a differential thermal balance (TG-DTA) (TG-8120 manufactured by Rigaku Corporation). The mass residual rate is set to the following value.

Mass residual rate (%) of layer B=mass residual rate (%) at 440° C.−mass residual rate (%) at 900° C.

### Layer A

The laminate according to the embodiment of the present disclosure includes a layer A.

Further, examples of a method for detecting or determining the layer configuration, the thickness of each layer, and the like in the film include the following methods.

First, a cross-sectional sample of the film is cut out by a microtome, and a layer configuration and a thickness of each layer are determined with an optical microscope. In a case where the determination with an optical microscope is difficult, the determination may be obtained by performing morphological observation with a scanning electron microscope (SEM), or component analysis by a time-of-flight secondary ion mass spectrometry (TOF-SIMS) or the like.

From the viewpoints of the dielectric loss tangent of the film, the laser processing suitability, and the level difference followability, a dielectric loss tangent of the layer A is preferably 0.01 or less, more preferably 0.005 or less, still more preferably 0.004 or less, and particularly preferably 0.003 or less. The lower limit value is not particularly set, and examples thereof include more than 0.

From the viewpoint of the dielectric loss tangent of the film and the laser processing suitability, the layer A preferably contains a polymer having a dielectric loss tangent of 0.01 or less.

In addition, from the viewpoint of the dielectric loss tangent of the film and the laser processing suitability, the layer A preferably contains a polymer having an aromatic ring, and more preferably contains a polymer having an aromatic ring and having a dielectric loss tangent of 0.01 or less.

Further, from the viewpoint of the dielectric loss tangent of the film and the laser processing suitability, the layer A preferably contains a polymer and polymer particles, and more preferably contains a polymer having a dielectric loss tangent of 0.01 or less and particles of a polymer having a dielectric loss tangent of 0.01 or less.

### Polymer Having Dielectric Loss Tangent of 0.01 or Less

From the viewpoints of the dielectric loss tangent of the film, the laser processing suitability, and the level difference followability, the dielectric loss tangent of the polymer contained in the layer A of the laminate according to the embodiment of the present disclosure is preferably 0.01 or less, more preferably 0.005 or less, still more preferably 0.004 or less, and particularly preferably 0.003 or less. The lower limit value is not particularly set, and examples thereof include more than 0.

From the viewpoints of the dielectric loss tangent of the film, the adhesiveness of the film to the metal (for example, the metal layer, the metal wire, or the like), and the heat resistance, the melting point Tm or the 5% mass-loss temperature Td of the polymer having a dielectric loss tangent of 0.01 or less is preferably 200° C. or higher, more preferably 250° C. or higher, still more preferably 280° C. or higher, and particularly preferably 300° C. or higher. The upper limit value thereof is not particularly limited, but is preferably 500° C. or lower and more preferably 420° C. or lower.

The melting point Tm in the present disclosure is defined as a value measured by a differential scanning calorimetry (DSC) device. 5 mg of a sample is put into a measurement pan of the DSC, and a peak temperature of an endothermic peak which appears in a case where the sample is heated from 30° C. at 10° C./min in a nitrogen stream is defined as the Tm of the film.

In addition, the 5% mass-loss temperature Td in the present disclosure is measured with a thermogravimetric analysis (TGA) device. That is, a mass of the sample put into the measurement pan is defined as an initial value, and a temperature at which the mass is reduced by 5% by mass with respect to the initial value due to the heating is defined as the 5% mass-loss temperature Td.

From the viewpoints of the dielectric loss tangent of the film, the adhesiveness to the metal, and the heat resistance, the glass transition temperature Tg of the polymer having a dielectric loss tangent of 0.01 or less is preferably 150° C. or higher, more preferably 200° C. or higher, and particularly preferably 200° C. or higher. The upper limit value thereof is not particularly limited, but is preferably lower than 350° C., more preferably 280° C. or lower, and further preferably lower than 280° C.

The glass transition temperature Tg in the present disclosure is defined as a value measured by a differential scanning calorimetry (DSC) device.

A weight-average molecular weight Mw of the polymer having a dielectric loss tangent of 0.01 or less is preferably 1,000 or more, more preferably 2,000 or more, and particularly preferably 5,000 or more. In addition, the weight-average molecular weight Mw of the polymer having a dielectric loss tangent of 0.01 or less is preferably 50,000 or less, more preferably 20,000 or less, and particularly preferably less than 13,000.

In the present disclosure, the type of the polymer having a dielectric loss tangent of 0.01 or less is not particularly limited, and a known polymer can be used.

Examples of the polymer having a dielectric loss tangent of 0.01 or less include thermoplastic resins such as a liquid crystal polymer, a fluorine-based polymer, a polymerized substance of a compound which has a cyclic aliphatic hydrocarbon group and a group having an ethylenically unsaturated bond, polyether ether ketone, polyolefin, polyamide, polyester, polyphenylene sulfide, aromatic polyether ketone, polycarbonate, polyethersulfone, polyphenylene ether and modified products thereof, and polyetherimide; elastomers such as a copolymer of glycidyl methacrylate and polyethylene; and thermosetting resins such as a phenol resin, an epoxy resin, a polyimide resin, and a cyanate resin.

Among these, from the viewpoint of dielectric loss tangent of the film, adhesiveness to metal, and heat resistance, at least one polymer selected from the group consisting of a liquid crystal polymer, a fluorine-based polymer, a polymerized substance of a compound which has a cyclic aliphatic hydrocarbon group and a group having an ethylenically unsaturated bond, polyphenylene ether, and aromatic polyether ketone is preferable, and at least one polymer selected from the group consisting of a liquid crystal polymer and a fluorine-based polymer is more preferable.

From the viewpoint of adhesiveness and mechanical strength of the film, a liquid crystal polymer is preferable, and from the viewpoint of heat resistance and dielectric loss tangent, a fluorine-based polymer is preferable.

### Liquid Crystal Polymer

From the viewpoints of the dielectric loss tangent of the film, the laser processing suitability, and the level difference followability, the layer A in the laminate according to the embodiment of the present disclosure preferably includes a liquid crystal polymer.

In the present disclosure, the type of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. Further, in a case where the liquid crystal polymer is a thermotropic liquid crystal polymer, the liquid crystal polymer is preferably a liquid crystal polymer which is molten at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, from the viewpoints of the dielectric loss tangent, the liquid crystallinity, and the thermal expansion coefficient of the film, the liquid crystal polymer is preferably a polymer having an aromatic ring, more preferably an aromatic polyester or an aromatic polyester amide, and particularly preferably an aromatic polyester amide.

Further, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

Further, it is preferable that the liquid crystal polymer is a wholly aromatic liquid crystal polymer formed of only an aromatic compound as a raw material monomer. Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine;
2) a liquid crystal polymer obtained by polycondensing a plurality of types of aromatic hydroxycarboxylic acids;
3) a liquid crystal polymer obtained by polycondensing (i) an aromatic dicarboxylic acid and (ii) at least one compound selected from the group consisting of an aromatic diol, an aromatic hydroxyamine, and an aromatic diamine;
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid, an aromatic diol, and an aromatic hydroxyamine, include a derivative (acylated product) obtained by acylating a hydroxy group and converting the acylated hydroxy group into an acyloxy group.

For example, the aromatic hydroxycarboxylic acid, the aromatic diol, and the aromatic hydroxyamine can be each replaced with an acylated product by acylating a hydroxy group and converting the acylated hydroxy group into an acyloxy group.

Examples of a polymerizable derivative of a compound having an amino group, such as an aromatic hydroxyamine or an aromatic diamine, include a derivative (acylated product) obtained by acylating an amino group and converting the acylated amino group to an acylamino group.

For example, the aromatic hydroxyamine and the aromatic diamine can be each replaced with an acylated product by acylating an amino group and converting the acylated amino group into an acylamino group.

From the viewpoint of liquid crystallinity, the dielectric loss tangent of the film, and adhesiveness to the metal, the liquid crystal polymer preferably has a constitutional unit represented by any of Formulae (1) to (3) (hereinafter, a constitutional unit represented by Formula (1) or the like may be referred to as a constitutional unit (1) or the like), more preferably has a constitutional unit represented by Formula (1), and particularly preferably has a constitutional unit represented by Formula (1), a constitutional unit represented by Formula (2), and a constitutional unit represented by Formula (3).

—O—Ar¹—CO— Formula (1)

—CO—Ar²—CO— Formula (2)

—X—Ar³—Y— Formula (3)

In Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group.

—Ar⁴—Z—Ar⁵— Formula (4)

In Formula (4), Ar⁴ and Ar⁵ each independently represent a phenylene group or a naphthylene group, and Z represents an oxygen atom, a sulfur atom, a carbonyl group, a sulfonyl group, or an alkylene group.

Examples of the halogen atom include a fluorine atom, a chlorine atom, a bromine atom, and an iodine atom.

Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group. The number of carbon atoms in the alkyl group is preferably 1 to 10.

Examples of the aryl group include a phenyl group, an o-tolyl group, an m-tolyl group, a p-tolyl group, a 1-naphthyl group, and a 2-naphthyl group. The number of carbon atoms in the aryl group is preferably 6 to 20.

In a case where the hydrogen atom is substituted with any of these groups, the number of each of substitutions in Ar¹, Ar², and Ar³ independently is preferably 2 or less and more preferably 1.

Examples of the alkylene group include a methylene group, a 1,1-ethanediyl group, a 1-methyl-1,1-ethanediyl group, a 1,1-butanediyl group, and a 2-ethyl-1,1-hexanediyl group. The number of carbon atoms in the alkylene group is preferably 1 to 10.

The constitutional unit (1) is a constitutional unit derived from an aromatic hydroxycarboxylic acid.

As the constitutional unit (1), an aspect in which Ar¹ represents a p-phenylene group (constitutional unit derived from p-hydroxybenzoic acid), and an aspect in which Ar¹ represents a 2,6-naphthylene group (constitutional unit derived from 6-hydroxy-2-naphthoic acid), or an aspect in which Ar¹ represents a 4,4′-biphenylylene group (constitutional unit derived from 4′-hydroxy-4-biphenylcarboxylic acid) is preferable.

The constitutional unit (2) is a constitutional unit derived from an aromatic dicarboxylic acid.

As the constitutional unit (2), an aspect in which Ar² represents a p-phenylene group (constitutional unit derived from terephthalic acid), an aspect in which Ar² represents an m-phenylene group (constitutional unit derived from isophthalic acid), an aspect in which Ar² represents a 2,6-naphthylene group (constitutional unit derived from 2,6-naphthalenedicarboxylic acid), or an aspect in which Ar² represents a diphenylether-4,4′-diyl group (constitutional unit derived from diphenylether-4,4′-dicarboxylic acid) is preferable.

The constitutional unit (3) is a constitutional unit derived from an aromatic diol, an aromatic hydroxylamine, or an aromatic diamine.

As the constitutional unit (3), an aspect in which Ar³ represents a p-phenylene group (constitutional unit derived from hydroquinone, p-aminophenol, or p-phenylenediamine), an aspect in which Ar³ represents an m-phenylene group (constitutional unit derived from isophthalic acid), or an aspect in which Ar³ represents a 4,4′-biphenylylene group (constitutional unit derived from 4,4′-dihydroxybiphenyl, 4-amino-4′-hydroxybiphenyl, or 4,4′-diaminobiphenyl) is preferable.

A content of the constitutional unit (1) is preferably 30 mol % or more, more preferably 30 mol % to 80 mol %, still more preferably 30 mol % to 60 mol %, and particularly preferably 30 mol % to 40 mol % with respect to the total amount of all constitutional units (a value obtained by dividing the mass of each constitutional unit (also referred to as “monomer unit”) constituting the liquid crystal polymer by the formula weight of each constitutional unit to calculate an amount (mole) equivalent to the substance amount of each constitutional unit and adding up the amounts).

The content of the constitutional unit (2) is preferably 35 mol % or less, more preferably 10 mol % to 35 mol %, still more preferably 20 mol % to 35 mol %, and particularly preferably 30 mol % to 35 mol % with respect to the total amount of all constitutional units.

The content of the constitutional unit (3) is preferably 35 mol % or less, more preferably 10 mol % to 35 mol %, still more preferably 20 mol % to 35 mol %, and particularly preferably 30 mol % to 35 mol % with respect to the total amount of all constitutional units.

The heat resistance, the strength, and the rigidity are likely to be improved as the content of the constitutional unit (1) increases, but the solubility in a solvent is likely to be decreased in a case where the content thereof is extremely large.

A proportion of the content of the constitutional unit (2) to the content of the constitutional unit (3) is expressed as [content of constitutional unit (2)]/[content of constitutional unit (3)] (mol/mol), and is preferably 0.9/1 to 1/0.9, more preferably 0.95/1 to 1/0.95, and still more preferably 0.98/1 to 1/0.98.

The liquid crystal polymer may have two or more kinds of each of the constitutional units (1) to (3) independently. In addition, the liquid crystal polymer may have a constitutional unit other than the constitutional units (1) to (3), but the content thereof is preferably 10 mol % or less and more preferably 5 mol % or less with respect to the total amount of all the constitutional units.

From the viewpoint of solubility in a solvent, the liquid crystal polymer preferably has, as the constitutional unit (3), a constitutional unit (3) in which at least one of X or Y is an imino group, that is, preferably has as the constitutional unit (3), at least one of a constitutional unit derived from an aromatic hydroxylamine or a constitutional unit derived from an aromatic diamine, and it is more preferable to have only a constitutional unit (3) in which at least one of X or Y is an imino group.

It is preferable that the liquid crystal polymer is produced by melt-polymerizing raw material monomers corresponding to the constitutional units constituting the liquid crystal polymer. The melt polymerization may be carried out in the presence of a catalyst. Examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino) pyridine and 1-methylimidazole; and preferred examples thereof include nitrogen-containing heterocyclic compounds. The melt polymerization may be further carried out by solid-state polymerization as necessary.

The lower limit value of a flow start temperature of the liquid crystal polymer is preferably 180° C. or higher, more preferably 200° C. or higher, and still more preferably 250° C. or higher, and the upper limit value of the flow start temperature thereof is preferably 350° C., more preferably 330° C., and still more preferably 310° C. In a case where the flow start temperature of the liquid crystal polymer is within the above-described range, the solubility, the heat resistance, the strength, and the rigidity are excellent, and the viscosity of the solution is appropriate.

The flow start temperature, also referred to as a flow temperature, is a temperature at which a viscosity of 4,800 Pa·s (48,000 poises) is exhibited in a case where the liquid crystal polymer is melted and extruded from a nozzle having an inner diameter of 1 mm and a length of 10 mm while the temperature is raised at a rate of 4° C./min under a load of 9.8 MPa (100 kg/cm²) using a capillary rheometer and is a guideline for the molecular weight of the liquid crystal polymer (see p. 95 of “Liquid Crystal Polymers—Synthesis/Molding/Applications—”, written by Naoyuki Koide, CMC Corporation, Jun. 5, 1987).

In addition, a weight-average molecular weight of the liquid crystal polymer is preferably 1,000,000 or less, more preferably 3,000 to 300,000, still more preferably 5,000 to 100,000, and particularly preferably 5,000 to 30,000. In a case where the weight-average molecular weight of the liquid crystal polymer is within the above-described range, a film after heat treatment is excellent in thermal conductivity, heat resistance, strength, and rigidity in the thickness direction.

### Fluorine-Based Polymer

From the viewpoint of heat resistance and mechanical strength, the polymer having a dielectric loss tangent of 0.01 or less is preferably a fluorine-based polymer.

In the present disclosure, the type of the fluorine-based polymer used as the polymer having a dielectric loss tangent of 0.01 or less is not particularly limited as long as the dielectric loss tangent thereof is 0.01 or less, and a known fluorine-based polymer can be used.

Examples of the fluorine-based polymer include polytetrafluoroethylene, polychlorotrifluoroethylene, polyvinylidene fluoride, polyvinyl fluoride, a perfluoroalkoxy fluorine-based polymer, a tetrafluoroethylene/hexafluoropropylene copolymer, an ethylene/tetrafluoroethylene copolymer, and an ethylene/chlorotrifluoroethylene copolymer.

Among these, polytetrafluoroethylene is preferable.

In addition, examples of the fluorine-based polymer include a fluorinated α-olefin monomer, that is, an α-olefin monomer containing at least one fluorine atom; and a homopolymer and a copolymer containing a constitutional unit derived from a non-fluorinated ethylenically unsaturated monomer reactive to the fluorinated α-olefin monomer, as necessary.

Examples of the fluorinated α-olefin monomer include CF₂═CF₂, CHF═CF₂, CH₂═CF₂, CHCl═CHF, CClF═CF₂, CCl₂═CF₂, CClF═CClF, CHF═CCl₂, CH₂═CClF, CCl₂═CClF, CF₃CF═CF₂, CF₃CF═CHF, CF₃CH═CF₂, CF₃CH═CH₂, CHF₂CH═CHF, CF₃CF═CF₂, and perfluoro (alkyl having 2 to 8 carbon atoms) vinyl ether (for example, perfluoromethyl vinyl ether, perfluoropropyl vinyl ether, and perfluorooctyl vinyl ether). Among these, at least one monomer selected from the group consisting of tetrafluoroethylene (CF₂═CF₂), chlorotrifluoroethylene (CClF═CF₂), (perfluorobutyl) ethylene, vinylidene fluoride (CH₂═CF₂), and hexafluoropropylene (CF₂═CFCF₃) is preferable.

Examples of the non-fluorinated monoethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluorine-based polymer include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluorine-based polymer may be used alone or in combination of two or more thereof.

The fluorine-based polymer is preferably at least one of FEP, PFA, ETFE, or PTFE. The FEP is available from Du Pont as the trade name of TEFLON (registered trademark) FEP or from DAIKIN INDUSTRIES, LTD. as the trade name of NEOFLON FEP; and the PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluorine-based polymer preferably includes PTFE. The PTFE can be included as a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluorine-based polymer may be a crosslinkable fluoropolymer having a crosslinkable group. The crosslinkable fluoropolymer can be crosslinked by a known crosslinking method in the related art. One of the representative crosslinkable fluoropolymers is a fluoropolymer having a (meth) acryloxy group. For example, the crosslinkable fluoropolymer can be represented by Formula:

H₂C═CR′COO—(CH₂)ₙ—R—(CH₂)ₙ—OOCR′═CH₂

In the formula, R is a fluorine-based oligomer chain having two or more constitutional units derived from the fluorinated α-olefin monomer or the non-fluorinated monoethylenically unsaturated monomer, R′ is H or —CH₃, and n is 1 to 4. R may be a fluorine-based oligomer chain having a constitutional unit derived from tetrafluoroethylene.

In order to initiate a radical crosslinking reaction through the (meth) acryloxy group in the fluorine-based polymer, by exposing the fluoropolymer having a (meth) acryloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

### Polymerized Substance of Compound Which has Cyclic Aliphatic Hydrocarbon Group and Group Having Ethylenically Unsaturated Bond

The polymer having a dielectric loss tangent of 0.01 or less may be a polymerized substance of a compound which has a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a constitutional unit formed from a monomer having a cyclic olefin such as norbornene and a polycyclic norbornene-based monomer, which is also referred to as a thermoplastic cyclic olefin-based resin.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

The polymerized substance of a compound which has a cyclic aliphatic hydrocarbon group and a group having an ethylenically unsaturated bond may be a polymer obtained by polymerizing at least one compound which has a cyclic aliphatic hydrocarbon group and a group having an ethylenically unsaturated bond, may be a polymerized substance of two or more kinds of the compound which has a cyclic aliphatic hydrocarbon group and a group having an ethylenically unsaturated bond, or may be a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

### Polyphenylene Ether

The layer A preferably contains a polyphenylene ether.

In a case where heat curing is performed after film formation, from the viewpoint of heat resistance and film-forming property, a weight-average molecular weight (Mw) of the polyphenylene ether is preferably 500 to 5,000 and more preferably 500 to 3,000. In addition, in a case where the heat curing is not performed, the weight-average molecular weight (Mw) of the polyphenylene ether is not particularly limited, but is preferably 3,000 to 100,000 and more preferably 5,000 to 50,000.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of hydroxyl groups or the number of the phenolic hydroxyl groups in the polyphenylene ether can be found, for example, from a standard value of a product of the polyphenylene ether. In addition, examples of the number of terminal hydroxyl groups or the number of terminal phenolic hydroxyl groups include a numerical value representing an average value of hydroxyl groups or phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and a compound mainly including the polyphenylene ether, such as poly(2,6-dimethyl-1,4-phenylene oxide). More specifically, for example, a compound having a structure represented by Formula (PPE) is preferable.

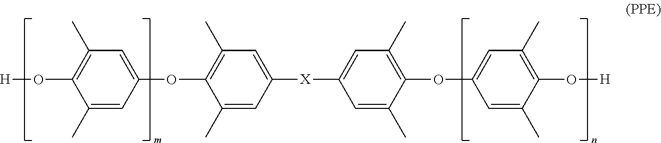

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

### Aromatic Polyether Ketone

The polymer having a dielectric loss tangent of 0.01 or less may be an aromatic polyether ketone.

The aromatic polyether ketone is not particularly limited, and a known aromatic polyether ketone can be used.

The aromatic polyether ketone is preferably a polyether ether ketone.

The polyether ether ketone is one type of the aromatic polyether ketone, and is a polymer in which bonds are arranged in the order of an ether bond, an ether bond, and a carbonyl bond (ketone). It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

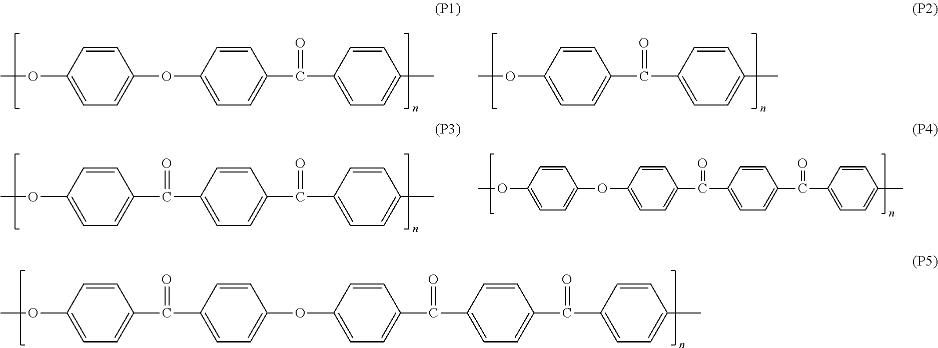

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

The polymer having a dielectric loss tangent of 0.01 or less is preferably a polymer soluble in a specific organic solvent (hereinafter, also referred to as “soluble polymer”).

Specifically, the soluble polymer according to the embodiment of the present disclosure is a liquid crystal polymer in which 0.1 g or more thereof is dissolved at 25° C. in 100 g of at least one solvent selected from the group consisting of N-methylpyrrolidone, N-ethylpyrrolidone, dichloromethane, dichloroethane, chloroform, N,N-dimethylacetamide, γ-butyrolactone, dimethylformamide, ethylene glycol monobutyl ether, and ethylene glycol monoethyl ether.

The layer A may contain only one kind of polymer having a dielectric loss tangent of 0.01 or less, or may contain two or more kinds thereof.

From the viewpoint of the dielectric loss tangent of the film and the adhesiveness to the metal, the content of the polymer having a dielectric loss tangent of 0.01 or less, which is preferably a liquid crystal polymer, in the layer A is preferably 10% by mass to 100% by mass, more preferably 20% by mass to 100% by mass, still more preferably 30% by mass to 100% by mass, and particularly preferably 40% by mass to 100% by mass with respect to the total mass of the layer A.

From the viewpoint of dielectric loss tangent of the film and adhesiveness to the metal, the content of the polymer having a dielectric loss tangent of 0.01 or less, which is preferably a liquid crystal polymer, in the film is preferably 20% by mass to 100% by mass, more preferably 30% by mass to 100% by mass, still more preferably 40% by mass to 100% by mass, and particularly preferably 50% by mass to 100% by mass with respect to the total mass of the film.

The content of the polymer having a dielectric loss tangent of 0.01 or less also includes the content of the polymer having a particulate dielectric loss tangent of 0.01 or less, which will be described later, is.

### Filler

The layer A may contain a filler from the viewpoint of a thermal expansion coefficient and adhesiveness to the metal.

The filler may be particulate or fibrous, and may be an inorganic filler or an organic filler. However, from the viewpoints of the dielectric loss tangent of the film, the laser processing suitability, and the level difference followability, an organic filler is preferable.

In the laminate according to the embodiment of the present disclosure, from the viewpoint of the thermal expansion coefficient and the adhesiveness to the metal, the number density of the filler is preferably larger inside the film than the surface of the film.

Here, the surface of the film refers to a surface (surface in contact with air or substrate) of the film outside, and a smaller one of a range of 3 μm in a depth direction from the most surface or a range of 10% or less of the thickness of the entire film from the most surface is defined as the “surface”. The inside of the film refers to a portion other than the surface of the film, that is, a surface (a surface not in contact with air or a substrate) inside the film, and is not limited, but in a range of +1.5 μm from the center in a thickness direction of the film or in a range of +5% of the total thickness from the center in the thickness direction of the film, one having a smaller numerical value is defined as “inside”.

As the organic filler, a known organic filler can be used.

Examples of a material of the organic filler include polyethylene, polystyrene, urea-formalin filler, polyester, cellulose, acrylic resin, fluorine-based polymer, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, as the organic filler, from the viewpoint of the dielectric loss tangent of the film, the laser processing suitability, and the level difference followability, fluorine-based polymer particles, polyester-based resin particles, polyethylene particles, liquid crystal polymer particles, or cellulose-based resin nanofibers are preferable, polytetrafluoroethylene particles, polyethylene particles, or liquid crystal polymer particles are more preferable, and liquid crystal polymer particles are particularly preferable. Here, the liquid crystal polymer particles are not limited, but refer to particles obtained by polymerizing a liquid crystal polymer and crushing the liquid crystal polymer with a crusher or the like to obtain powdery liquid crystal. The liquid crystal polymer particles are preferably smaller than the thickness of each layer.

From the viewpoints of the dielectric loss tangent of the film, the laser processing suitability, and the level difference followability, the average particle diameter of the organic filler is preferably 5 nm to 20 μm and more preferably 100 nm to 10 μm.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, as the inorganic filler, from the viewpoint of thermal expansion coefficient and adhesiveness to the metal, metal oxide particles or fibers are preferable, silica particles, titania particles, or glass fibers are more preferable, and silica particles or glass fibers are particularly preferable.

An average particle diameter of the inorganic filler is preferably approximately 20% to approximately 40% of the thickness of a layer A, and for example, the average particle diameter may be selected from 25%, 30%, or 35% of the thickness of the layer A. In a case where the particles or fibers are flat, the average particle diameter indicates a length in a short side direction.

In addition, from the viewpoint of thermal expansion coefficient and adhesiveness to the metal, the average particle diameter of the inorganic filler is preferably 5 nm to 20 μm, more preferably 10 nm to 10 μm, still more preferably 20 nm to 1 μm, and particularly preferably 25 nm to 500 nm.

The layer A may contain only one or two or more kinds of the fillers.

From the viewpoint of adhesiveness to the metal, it is preferable that a content of the filler in the layer A is smaller than a content of the filler in the layer B.

In addition, from the viewpoint of laser processing suitability and adhesiveness to the metal, the content of the filler in the layer A is preferably 10% by mass to 90% by mass and more preferably 30% by mass to 80% by mass with respect to the total mass of the layer A.

A content of a filler such as polyethylene and an olefin-based elastomer is, for example, preferably 50% by volume to 90% by volume, and more preferably 75% by volume to 85% by volume. In this case, the content of the filler in the layer A is preferably 55% by mass to 90% by mass, and more preferably 80% by mass to 85% by mass with respect to the total mass of the layer A.

### Other Additives

The layer A may contain an additive other than the above-described components.

Known additives can be used as other additives. Specific examples of the other additives include a curing agent, a leveling agent, an antifoaming agent, an antioxidant, an ultraviolet absorbing agent, a flame retardant, and a colorant.

In addition, the layer A may contain other resins other than the above-described polymer and polymer particles as other additives.

Examples of other resins include thermoplastic resins such as polypropylene, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

The total content of the other additives in the layer A is preferably 25 parts by mass or less, more preferably 10 parts by mass or less, and still more preferably 5 parts by mass or less with respect to 100 parts by mass of the content of the polymer having a dielectric loss tangent of 0.01 or less.

From the viewpoints of the dielectric loss tangent of the film and the adhesiveness to the metal, the average thickness of the layer A is preferably thicker than the average thickness of the layer B.

From the viewpoint of dielectric loss tangent of the film and adhesiveness to the metal, a value of T^{A}/T^{B}, which is a ratio of the average thickness T^{A} of the layer A to the average thickness T^{B} of the layer B, is preferably 0.5 to 10, more preferably 0.5 to 5, still more preferably more than 0.6 and 3 or less, and particularly preferably more than 0.6 and 2 or less.

In addition, the average thickness of the layer A is not particularly limited, but from the viewpoint of dielectric loss tangent of the film and adhesiveness to the metal, the average thickness thereof is preferably 5 μm to 90 μm, more preferably 10 μm to 70 μm, and particularly preferably 15 μm to 60 μm.

A measuring method of the average thickness of each layer in the laminate according to the embodiment of the present disclosure is as follows.

The thickness of each layer is evaluated by cutting the film with a microtome and observing the cross section with an optical microscope. Three or more sites of the cross-sectional sample are cut out, the thickness is measured at three or more points in each cross section, and the average value thereof is defined as the average thickness.

### Layer B

The laminate according to the embodiment of the present disclosure includes the layer B on at least one surface of the layer A.

From the viewpoint of laser processing suitability and level difference followability, the above-described layer B preferably includes a cured product obtained by curing a thermosetting compound, and more preferably includes a cured product obtained by curing a thermosetting resin.

In addition, from the viewpoint of laser processing suitability and level difference followability, the above-described layer B preferably contains a thermoplastic resin, and more preferably contains a thermoplastic elastomer.

Examples of the thermosetting compound include compounds having a maleimide group, an allyl group, a vinyl group, an epoxy group, an oxetanyl group, a cyanate group, a benzoxazine group, and the like.

From the viewpoint of laser processing suitability and level difference followability, the thermosetting compound preferably has at least one group selected from the group consisting of a maleimide group, an allyl group, a vinyl group, a cyanate group, and a benzoxazine group, and from the viewpoint of dielectric loss tangent, it is more preferable to contain a resin having at least one group selected from the group consisting of a maleimide group, an allyl group, and a vinyl group.

From the viewpoint of laser processing suitability and level difference followability, the above-described thermosetting compound is preferably a compound having a weight-average molecular weight (Mw) of 100 or more, more preferably a compound having a weight-average molecular weight of 200 or more, and particularly preferably a compound having a weight-average molecular weight of 300 or more.

In addition, from the viewpoint of laser processing suitability and level difference followability, the weight-average molecular weight of the thermosetting compound is preferably 100,000 or less, more preferably 200 to 50,000, still more preferably 300 to 30,000, and particularly preferably 300 to 10,000.

Specific examples of the thermosetting compound include a bismaleimide resin, an allyl group-containing polyphenylene ether resin, an allyl group-containing polyarylate resin, and a vinyl group-containing polyphenylene ether resin.

The layer B may contain only one kind of thermosetting compound or may contain two or more kinds thereof.

In addition, from the viewpoint of laser processing suitability and level difference followability, the content of the cured product obtained by curing the thermosetting compound in the layer B is preferably 10% by mass to 80% by mass, and more preferably 15% by mass to 50% by mass with respect to the total mass of the layer B.

Examples of the above-described thermoplastic resin include a polyurethane resin, a polyester resin, a (meth) acrylic resin, a polystyrene resin, a fluorine-based polymer, a polyimide resin, a fluorinated polyimide resin, a polyamide resin, a polyamideimide resin, a polyether imide resin, a cellulose acylate resin, a polyurethane resin, a polyether ether ketone resin, a polycarbonate resin, a polyolefin resin (for example, a polyethylene resin, a polypropylene resin, a resin consisting of a cyclic olefin copolymer, and an alicyclic polyolefin resin), a polyarylate resin, a polyether sulfone resin, a polysulfone resin, a fluorene ring-modified polycarbonate resin, an alicyclic ring-modified polycarbonate resin, and a fluorene ring-modified polyester resin.

The thermoplastic elastomer is not particularly limited, and examples thereof include an elastomer having a constitutional repeating unit derived from styrene (polystyrene-based elastomer), a polyester-based elastomer, a polyolefin-based elastomer, a polyurethane-based elastomer, a polyamide-based elastomer, a polyacryl-based elastomer, a silicone-based elastomer, and a polyimide-based elastomer. The thermoplastic elastomer may be a hydride.

Examples the polystyrene-based elastomer include a styrene-butadiene-styrene block copolymer (SBS), a styrene-isoprene-styrene block copolymer (SIS), polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), and hydrides thereof.

Among these, from the viewpoint of dielectric loss tangent, laser processing suitability, and level difference followability, the layer B preferably contains a thermoplastic resin having a constitutional unit having an aromatic hydrocarbon group as the thermoplastic resin, more preferably contains a polystyrene-based elastomer, and particularly preferably contains a styrene-butadiene-styrene block copolymer or a hydrogenated styrene-ethylene-butylene-styrene block copolymer.

In addition, from the viewpoint of dielectric loss tangent, laser processing suitability, and level difference followability, a polystyrene-based elastomer or a hydrogenated polystyrene-based elastomer is preferable as the thermoplastic resin.

In the layer B, only one kind of thermoplastic compound may be used, or two or more kinds thereof may be used.

In addition, the content of the thermoplastic resin in the layer B is not particularly limited, but from the viewpoint of dielectric loss tangent of the film, laser processing suitability, and adhesiveness to the metal, the content of the thermoplastic resin is preferably 10% by mass to 95% by mass, more preferably 20% by mass to 90% by mass, and particularly preferably 50% by mass to 85% by mass with respect to the total mass of the layer B.

From the viewpoint of dielectric loss tangent, laser processing suitability, adhesiveness to the metal, and level difference followability, it is more preferable that the layer B contains a filler.

Preferred aspects of the filler which is used in the layer B are the same as the preferred aspects of the filler which is used in the layer A, except as described below.

In addition, from the viewpoint of dielectric loss tangent, laser processing suitability, and level difference followability, it is preferable that the layer B contains an inorganic filler as the filler used in the layer B.

Among these, silica particles are particularly preferable.

Furthermore, from the viewpoint of dielectric loss tangent, laser processing suitability, and level difference followability, it is preferable that the layer B contains polymer particles having a dielectric loss tangent of 0.01 or less. Preferred examples of the polymer particles having a dielectric loss tangent of 0.01 or less include liquid crystal polymer particles and fluorine-based resin particles.

The layer B may contain only one or two or more kinds of the fillers.

In addition, from the viewpoint of laser processing suitability and adhesiveness to the metal, the content of the filler in the layer B is preferably 5% by mass to 70% by mass and more preferably 10% by mass to 50% by mass with respect to the total mass of the layer B.

The layer B may contain a leveling agent. Examples thereof include a hydrocarbon-based, silicone-based, or fluorine-based compound, and preferred examples thereof include a hydrocarbon-based, silicone-based, or fluorine-based surfactant. Examples of the fluorine-based surfactant include MEGAFACE series manufactured by DIC Corporation, such as MEGAFACE F-444, SURFLON series manufactured by AGC SEIMI CHEMICAL Co., Ltd., such as SURFLON S-221, and FTERGENT series manufactured by NEOS COMPANY LIMITED, such as FTERGENT 100. Further, the surfactant may be a polymer, and examples thereof include an acrylic polymer containing, as an essential component, a monomer containing a fluorinated alkyl group, and a siloxane-based polymer in which a chain skeleton consists of a Si-O bond.

The layer B may contain an additive other than those described above.

Preferred aspects of other additives which are used in the layer B are the same as the preferred aspects of other additives which are used in the layer A, except as described below.

In addition, an average thickness of the layer B is not particularly limited, but from the viewpoints of the dielectric loss tangent of the film, the laser processing suitability, and the level difference followability, the average thickness is preferably 1 μm to 90 μm, more preferably 5 μm to 60 μm, and particularly preferably 10 μm to 40 μm.

### Conductive Pattern

The laminate according to the embodiment of the present disclosure has a conductive pattern in contact with at least a part of the above-described layer B.

In addition, the conductive pattern is preferably a conductive pattern of a metal (for example, gold, silver, copper, iron, or the like), and more preferably a conductive pattern of copper.

From the viewpoint of reducing transmission loss of a high-frequency signal, a surface roughness Rz of the above-described conductive pattern on the side in contact with the above-described layer B is preferably less than 1 μm, more preferably 0.5 μm or less, and particularly preferably 0.3 μm or less.

In addition, the surface roughness Rz of the conductive pattern is preferably small, and thus the lower limit value thereof is not particularly set, but is, for example, 0 or more.

The “surface roughness Rz” in the present disclosure refers to a value expressed in micrometer, which is the total value of the maximum value of height of peak and the maximum value of depth of valley observed on a roughness curve over the reference length.

In the present disclosure, the surface roughness Rz of the conductive pattern is measured by the following method.

Using a noncontact surface/layer cross-sectional shape measurement system VertScan (manufactured by MITSUBISHI CHEMICAL SYSTEMS, Inc.), a square of 465.48 μm in length and 620.64 μm in width is measured to create a roughness curve on the surface of the measurement object (conductive pattern) and create an average line of the roughness curve. A portion corresponding to the reference length is extracted from the roughness curve. The surface roughness Rz of the measurement object is measured by obtaining the total value of the maximum value of height of peak (that is, height from the average line to summit) and the maximum value of depth of valley (that is, depth from the average line to valley bottom) observed in the extracted roughness curve.

The average thickness of the conductive pattern is not particularly limited, but is preferably 0.1 nm to 30 μm, more preferably 0.1 μm to 20 μm, and still more preferably 1 μm to 18 μm. The copper foil may be copper foil with a carrier formed on a support (carrier) to be peelable. As the carrier, a known carrier can be used. An average thickness of the carrier is not particularly limited, but is preferably 5 μm to 100 μm and more preferably 10 μm to 50 μm.

In addition, the above-described conductive pattern preferably has a known surface treatment layer (for example, a chemical treatment layer) on the surface of the side in contact with the film to ensure adhesion to the resin. In addition, it is preferable that the above-described interactable group is a group corresponding to the functional group of the compound having a functional group, which is contained in the above-described film, such as an amino group and an epoxy group, and a hydroxy group and an epoxy group.

Examples of the interactable group include a group mentioned as the functional group in the above-described compound having a functional group.

Among these, from the viewpoint of adhesiveness and ease of performing a treatment, a covalent-bondable group is preferable, an amino group or a hydroxy group is more preferable, and an amino group is particularly preferable.

The conductive pattern in the laminate according to the embodiment of the present disclosure may be a circuit pattern.

Preferred examples of the method of producing the conductive pattern in the laminate according to the embodiment of the present disclosure include a method of processing a metal layer into a desired circuit pattern by etching. The etching method is not particularly limited, and a known etching method can be used.

### Layer C

It is preferable that the laminate according to the embodiment of the present disclosure further includes a layer C, and from the viewpoint of adhesiveness to the metal, it is more preferable that the above-described layer B, the above-described layer A, and the layer C are provided in this order.

The layer C is preferably an adhesive layer.

In addition, a layer similar to the above-described layer B may be separately provided as the layer C. That is, the layer B may be provided on both surfaces of the layer A. From the viewpoint of the dielectric loss tangent of the film and the laser processing suitability, the layer C preferably contains a polymer having a dielectric loss tangent of 0.01 or less.

The preferred aspect of the polymer having a dielectric loss tangent of 0.01 or less, which is used for the layer C, is the same as the preferred aspect of the polymer having a dielectric loss tangent of 0.01 or less, which is used for the layer A, except as described later.

The liquid crystal polymer, which is contained in the layer C, may be the same as or different from the polymer having a dielectric loss tangent is 0.01 or less, which contained in the layer A or the layer B, but from the viewpoint of the adhesiveness between the layer A and the layer C, the layer C preferably contains the same polymer as the polymer having a dielectric loss tangent is 0.01 or less, which is contained in the layer A.

From the viewpoint of adhesiveness to the metal, the content of the polymer having a dielectric loss tangent of 0.01 or less in the layer C is preferably equal to or less than the content of the polymer having a dielectric loss tangent of 0.01 or less in the layer A.

From the viewpoints of the dielectric loss tangent of the film and the adhesiveness to the metal, the content of the polymer having a dielectric loss tangent of 0.01 or less in the layer B with respect to the total mass of the film is preferably 10% by mass to 99% by mass, more preferably 20% by mass to 95% by mass, still more preferably 30% by mass to 90% by mass, and particularly preferably 40% by mass to 80% by mass.

In addition, from the viewpoint of the dielectric loss tangent of the film and the laser processing suitability, the layer C preferably includes a polymer having an aromatic ring, and more preferably includes a polymer having an aromatic ring, and being a resin having an ester bond and an amide bond, and having a dielectric loss tangent of 0.01 or less.

In addition, from the viewpoint of adhesiveness, the layer C preferably contains an epoxy resin.

The epoxy resin is preferably a crosslinked product of a polyfunctional epoxy compound. The polyfunctional epoxy compound refers to a compound having two or more epoxy groups. The number of epoxy groups in the polyfunctional epoxy compound is preferably 2 to 4.

The layer C preferably contains a leveling agent. Examples thereof include a hydrocarbon-based, silicone-based, or fluorine-based compound, and preferred examples thereof include a hydrocarbon-based, silicone-based, or fluorine-based surfactant. Examples of the fluorine-based surfactant include MEGAFACE series manufactured by DIC Corporation, such as MEGAFACE F-444, SURFLON series manufactured by AGC SEIMI CHEMICAL Co., Ltd., such as SURFLON S-221, and FTERGENT series manufactured by NEOS COMPANY LIMITED, such as FTERGENT 100. Further, the surfactant may be a polymer, and examples thereof include an acrylic polymer containing, as an essential component, a monomer containing a fluorinated alkyl group, and a siloxane-based polymer in which a chain skeleton consists of a Si—O bond.

Examples of the polyfunctional epoxy compound include a polyfunctional epoxy compound having a glycidyl ether group, a polyfunctional epoxy compound having a glycidyl ester group, and a polyfunctional epoxy compound having a glycidylamino group.

Examples of the polyfunctional epoxy compound having a glycidyl ether group include ethylene glycol diglycidyl ether, resorcinol diglycidyl ether, neopentyl glycol diglycidyl ether, 1,6-hexanediol diglycidyl ether, bisphenol A diglycidyl ether, trimethylolpropane polyglycidyl ether, polyglycerin polyglycidyl ether, glycerin polyglycidyl ether, pentaerythritol polyglycidyl ether, diglycerin polyglycidyl ether, sorbitol polyglycidyl ether, polybutadiene diglycidyl ether, diethylene glycol diglycidyl ether, polyethylene glycol diglycidyl ether, dipropylene glycol diglycidyl ether, and 1,4-butanediol diglycidyl ether.

Examples of the polyfunctional epoxy compound having a glycidyl ester group include a diglycidyl phthalate ester, a diglycidyl terephthalate ester, a diglycidyl hexahydrophthalate ester, and a diglycidyl dimerate.

Examples of the compound having a glycidylamino group include N,N,N′,N′-tetraglycidyl-4,4′-diaminodiphenylmethane and 4,4′-methylenebis(N,N-diglycidylaniline).

Examples of the polyfunctional epoxy compound having a glycidyl ether group and a glycidylamino group include N,N-diglycidyl-4-glycidyloxyaniline.

Among these, from the viewpoint of the curing properties and an interaction with the metal surface, the epoxy resin is preferably a crosslinked substance of a polyfunctional epoxy compound having a glycidylamino group, and more preferably at least one crosslinked substance selected from the group consisting of N,N-diglycidyl-4-glycidyloxyaniline and N,N,N′,N′-tetraglycidyl-4,4′-diaminodiphenylmethane.

In particular, from the viewpoints of the dielectric loss tangent of the film, the laser processing suitability, and the adhesiveness to the metal layer, it is preferable that the layer C contains aromatic polyester amide and an epoxy resin.

The layer C may contain a filler.

Preferred aspects of the filler which is used in the layer C are the same as the preferred aspects of the filler which is used in the layer B, except as described below.

A content of the filler in the layer C is not particularly limited and can be arbitrarily set. However, in a case where metal layers are provided on both surfaces of the film, from the viewpoint of adhesiveness to the metal, it is preferable that the content of the filler in the layer C is smaller than the content of the filler in the layer A.

In addition, in the case where metal layers are provided on both surfaces of the film, from the viewpoint of adhesiveness to the metal, it is preferable that the layer C does not contain the filler or the content of the filler in the layer C is more than 0% by volume and 20% by volume or less with respect to the total volume of the layer C; it is more preferable that the layer C does not contain the filler or the content of the filler in the layer C is more than 0% by volume and 10% by volume or less with respect to the total volume of the layer C; it is still more preferable that the layer C does not contain the filler or the content of the filler in the layer C is more than 0% by volume and 5% by volume or less with respect to the total volume of the layer C; and it is particularly preferable that the layer C does not contain the filler.

The content of the filler in the layer C is preferably 0% by mass to 15% by mass, and more preferably 0% by mass to 5% by mass with respect to the total mass of the layer C.

A content of a filler such as polyethylene and an olefin-based elastomer is, for example, preferably 50% by volume to 90% by volume, and more preferably 75% by volume to 85% by volume. In this case, the content of the filler in the layer C is preferably 55% by mass to 90% by mass, and more preferably 80% by mass to 85% by mass with respect to the total mass of the layer C.

The layer C may contain an additive other than those described above.

Preferred aspects of other additives which are used in the layer C are the same as the preferred aspects of other additives which are used in the layer A, except as described below.

From the viewpoint of dielectric loss tangent of the film and adhesiveness to the metal, it is preferable that an average thickness of the layer C is smaller than an average thickness of the layer A.

From the viewpoint of dielectric loss tangent of the film and adhesiveness to the metal, a value of T^{A}/T^{C}, which is a ratio of the average thickness T^{A} of the layer A to an average thickness T^{C} of the layer C, is preferably more than 1, more preferably 2 to 100, still more preferably 2.5 to 20, and particularly preferably 3 to 10.

From the viewpoint of dielectric loss tangent of the film and adhesiveness to the metal, a value of T^{B}/T^{C}, which is a ratio of the average thickness T^{B} of the layer B to the average thickness T^{C} of the layer C, is preferably more than 1, more preferably 2 to 100, still more preferably 2.5 to 20, and particularly preferably 3 to 10.

Further, from the viewpoint of the dielectric loss tangent of the film and the adhesiveness to the metal, the average thickness of the layer C is preferably 0.1 nm to 20 μm, more preferably 0.1 nm to 5 μm, and still more preferably 1 nm to 1 μm.

From the viewpoint of strength and electrical characteristics (characteristic impedance) in a case of being laminated with the metal layer, an average thickness of the laminate according to the embodiment of the present disclosure is preferably 6 μm to 200 μm, more preferably 12 μm to 100 μm, and particularly preferably 20 μm to 80 μm.

The average thickness of the film is measured at optional five sites using an adhesive film thickness meter, for example, an electronic micrometer (product name, “KG3001A”, manufactured by Anritsu Corporation), and the average value of the measured values is defined as the average thickness of the film.

### Manufacturing Method of Laminate

### Film Formation

The manufacturing method of a laminate according to the embodiment of the present disclosure is not particularly limited, and a known method can be referred to.

Suitable examples of the manufacturing method of a laminate according to the embodiment of the present disclosure include a co-casting method, a multilayer coating method, and a co-extrusion method. Among these, the co-casting method is particularly preferable for formation of a relatively thin film, and the co-extrusion method is particularly preferable for formation of a thick film.

In a case where the film is manufactured by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer, such as the polymer having a dielectric loss tangent of 0.01 or less or the liquid crystal polymer, and the compound having a functional group, in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

The solvent preferably contains an aprotic compound (particularly, an aprotic compound having no halogen atom) for low corrosiveness and easiness to handle. A proportion of the aprotic compound to the whole solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to contain an amide such as N,N-dimethylformamide, N,N-dimethylacetamide, tetramethylurea, and N-methylpyrrolidone, or an ester such as γ-butyrolactone; and it is more preferable to contain N,N-dimethylformamide, N,N-dimethylacetamide, or N-methylpyrrolidone.

In addition, as the solvent, it is preferable to contain a compound having a dipole moment of 3 to 5, because the above-described polymer such as the liquid crystal polymer can be easily dissolved. A proportion of the compound having a dipole moment of 3 to 5 to the whole solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, it is preferable to contain a compound having a boiling point of 220° C. or lower at 1 atm, because the solvent is easily removed. A proportion of the compound having a boiling point of 220° C. or lower at 1 atm to the whole solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in a case where the laminate according to the embodiment of the present disclosure is manufactured by the above-described manufacturing method such as the co-casting method, the multilayer coating method, and the co-extrusion method, the laminate may include a support. In addition, in a case where the metal layer (metal foil) or the like used in the laminate described later is used as the support, the support may be used as it is without being peeled off.

Examples of the support include a metal drum, a metal band, a glass plate, a resin film, and a metal foil. Among these, a metal drum, a metal band, or a resin film is preferable.

Examples of the resin film include a polyimide (PI) film, and examples of commercially available products thereof include U-PILEX S and U-PILEX R (manufactured by UBE Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. A hard chrome plating, a fluorine-based polymer, or the like can be used as the surface treatment layer.

An average thickness of the support is not particularly limited, but is preferably 25 μm or more and 75 μm or less and more preferably 50 μm or more and 75 μm or less.

In addition, a method for removing at least a part of the solvent from a cast or applied film-like composition (a casting film or a coating film) is not particularly limited, and a known drying method can be used.

### Stretching

In the laminate according to the embodiment of the present disclosure, stretching can be combined as appropriate from the viewpoint of controlling molecular alignment and adjusting linear expansion coefficient and mechanical properties. The stretching method is not particularly limited, and a known method can be referred to, and the stretching method may be carried out in a solvent-containing state or in a dry film state. The stretching in the solvent-containing state may be carried out by gripping and stretching the film, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

In addition, it is preferable that the manufacturing method of a laminate according to the embodiment of the present disclosure includes a step of curing the curable compound with heat.

The heat application means is not particularly limited, and known means for applying heat, such as a heater, can be used.

The heat application conditions are not particularly limited, and the heat treatment can be carried out at a desired temperature and time in a known atmosphere.

### Bonding

A method of bonding the above-described layer B to the conductive pattern is not particularly limited, and a known laminating method and a hot pressing method can be used.

### Heat Treatment of Layer B

The manufacturing method of a laminate according to the embodiment of the present disclosure preferably includes a step of subjecting the layer B to a heat treatment (annealing) in a case of bonding the conductive pattern.

Specifically, from the viewpoint of dielectric loss tangent, adhesiveness, laser processing suitability, and level difference followability, the heat treatment temperature in the above-described heat treatment step is preferably 240° C. or lower, more preferably 120° C. to 220° C., still more preferably 140° C. to 200° C., and particularly preferably 150° C. to 200° C. The heat treatment time is preferably 15 minutes to 10 hours and more preferably 30 minutes to 5 hours.

### Heat Treatment

The manufacturing method of a laminate according to the embodiment of the present disclosure preferably includes a step of subjecting the layer A to a heat treatment (annealing) before forming the layer B.

Specifically, from the viewpoint of dielectric loss tangent and peel strength, the heat treatment temperature in the above-described step of heat-treating is preferably 260° C. to 370° C., more preferably 280° C. to 360° C., and particularly preferably 300° C. to 350° C. The heat treatment time is preferably 15 minutes to 10 hours and more preferably 30 minutes to 5 hours.

In addition, the manufacturing method of a laminate according to the embodiment of the present disclosure may include other known steps as necessary.

### Applications

The laminate according to the embodiment of the present disclosure can be used for various applications. Among the various applications, the laminate can be used suitably for an electronic component such as a printed wiring board and more suitably for a flexible printed circuit board.

### Film

The film according to the embodiment of the present disclosure includes a layer A, and a layer B on at least one surface of the layer A, in which a dielectric loss tangent at 28 GHz is 0.01 or less, an elastic modulus of the layer B at 160° C. is 0.5 MPa or less, and the layer B contains a thermosetting resin.

The preferred aspects of the layer A and the layer B other than the cured product obtained by curing the thermosetting resin in the film according to the embodiment of the present disclosure are the same as the preferred aspects of the layer A and the layer B of the laminate according to the embodiment of the present disclosure, respectively.

In addition, the laminate according to the embodiment of the present disclosure is obtained by attaching a conductive pattern to the film according to the embodiment of the present disclosure and curing the layer B, and regarding the aspect that does not change before and after curing, the preferred aspect of the film according to the embodiment of the present disclosure is the same as the preferred aspect of the laminate according to the embodiment of the present disclosure.

In addition, the film according to the embodiment of the present disclosure preferably does not have a conductive pattern.

The film according to the embodiment of the present disclosure has a dielectric loss tangent of 0.01 or less at 28 GHz, and the elastic modulus of the above-described layer B is 0.5 MPa or less at 160° C. The elastic modulus at 160° C. is reduced due to a thermosetting resin in the above-described layer B, the film exhibits excellent level difference followability due to the layer B containing the thermosetting resin, and when thermally cured during or after the bonding of conductive patterns or the like, the heat resistance of layer B improves. Therefore, it is possible to provide a film that excels in both level difference followability and laser processing suitability.

### Elastic Modulus of Layer B at 160° C.

The elastic modulus of the layer B in the film according to the embodiment of the present disclosure at 160° C. is 0.5 MPa or less, and from the viewpoint of laser processing suitability and level difference followability, the elastic modulus is preferably 0.45 MPa or less, more preferably 0.40 MPa or less, and particularly preferably 0.01 MPa to 0.35 MPa.

The elastic modulus in the present disclosure is measured by the following method.

First, the film or the laminate is cut in cross section with a microtome or the like, and the layer A or the layer B is specified from an image observed with an optical microscope. Next, the elastic modulus of the specified layer A or layer B was measured as an indentation elastic modulus using a nanoindentation method. The indentation elastic modulus is measured by using a microhardness tester (product name “DUH-W201”, manufactured by Shimadzu Corporation) to apply a load at a loading rate of 0.28 mN/sec with a Vickers indenter at 160° C., holding a maximum load of 10 mN for 10 seconds, and then unloading at a loading rate of 0.28 mN/sec.

The measurement is also performed in the layers other than the layer A and the layer B. In addition, in a case where each layer is measured, an unnecessary layer may be scraped off with a razor or the like to produce an evaluation sample of only the target layer. In addition, in a case where it is difficult to take out the single film because the thickness of the layer is thin, a layer to be measured may be scraped off with a razor or the like, and the obtained powdery sample may be used.

The above-described layer B in the film according to the embodiment of the present disclosure contains a thermosetting resin, and from the viewpoint of laser processing suitability and level difference followability, it is preferable that the thermosetting resin has at least one group selected from the group consisting of a maleimide group, an allyl group, and a vinyl group.

The layer B may contain only one kind of thermosetting resin, or may contain two or more kinds thereof.

In addition, from the viewpoint of laser processing suitability and level difference followability, the content of the thermosetting resin in the layer B is preferably 10% by mass to 80% by mass, and more preferably 15% by mass to 50% by mass with respect to the total mass of the layer B.

### Thermosetting Film

The thermosetting film according to the embodiment of the present disclosure includes a thermosetting compound, and a thermoplastic elastomer, in which the thermosetting compound has at least one group selected from the group consisting of a maleimide group, an allyl group, and a vinyl group.

A preferred aspect of the thermosetting film according to the embodiment of the present disclosure is the same as the preferred aspect of the layer B of the film in the embodiment of the present disclosure described above, except as described below.

From the viewpoint of electrostatic loss tangent, laser processing suitability, and level difference followability, the thermosetting film according to the embodiment of the present disclosure preferably contains at least one selected from the group consisting of a polyimide, a liquid crystal polymer, a fluorine-based polymer, and an inorganic filler, and more preferably contains at least one selected from the group consisting of polyimide particles, liquid crystal polymer particles, fluorine-based polymer particles, and an inorganic filler.

In addition, from the viewpoint of electrostatic loss tangent, laser processing suitability, and level difference followability, the thermosetting film according to the embodiment of the present disclosure preferably contains aromatic polyester amide, and more preferably contains aromatic polyester amide particles.

From the viewpoint of laser processing suitability and level difference followability, the above-described thermosetting compound is preferably a compound (resin) having a weight-average molecular weight (Mw) of 100 or more, more preferably a compound having a weight-average molecular weight of 200 or more, and particularly preferably a compound having a weight-average molecular weight of 300 or more.

In addition, from the viewpoint of laser processing suitability and level difference followability, the weight-average molecular weight of the thermosetting compound is preferably 100,000 or less, more preferably 200 to 50,000, still more preferably 300 to 30,000, and particularly preferably 300 to 10,000.

The layer B may contain only one kind of thermosetting compound or may contain two or more kinds thereof.

In addition, from the viewpoint of laser processing suitability and level difference followability, the content of the thermosetting compound in the layer B is preferably 10% by mass to 80% by mass, and more preferably 15% by mass to 50% by mass with respect to the total mass of the layer B.

From the viewpoint of laser processing suitability and level difference followability, the elastic modulus of the thermosetting film according to the embodiment of the present disclosure at 160° C. is preferably 0.5 MPa or less, more preferably 0.45 MPa or less, still more preferably 0.40 MPa or less, and particularly preferably 0.01 MPa to 0.35 MPa.

From the viewpoint of dielectric constant, laser processing suitability, and level difference followability, the dielectric loss tangent of the thermosetting film according to the embodiment of the present disclosure at 28 GHz is preferably 0.01 or less, more preferably 0.008 or less, still more preferably 0.005 or less, particularly preferably 0.004 or less, and most preferably more than 0 and 0.003 or less.

### Manufacturing Method of Wiring Board

The manufacturing method of a wiring board according to the embodiment of the present disclosure is not particularly limited as long as it is a method using the film according to the embodiment of the present disclosure or the thermosetting film according to the embodiment of the present disclosure, and it is preferable that the method includes an overlaying step of overlaying the film according to the embodiment of the present disclosure or the thermosetting film according to the embodiment of the present disclosure on the wiring pattern of the base material with a wiring pattern from the above-described layer B side, and a heating step of heating the base material with a wiring pattern and the film in a state of being overlaid to obtain a wiring board.

In addition, in the manufacturing method of a wiring board according to the embodiment of the present disclosure, the overlaying step and the heating step may be performed at the same time.

Further, in the manufacturing method of a wiring board according to the embodiment of the present disclosure, the above-described manufacturing method of a laminate according to the embodiment of the present disclosure can be appropriately referred to.

The base material with a wiring pattern is not particularly limited, and a known base material can be used.

Examples of a preferred material of the wiring pattern include the same materials as those of the above-described conductive pattern.

A method of attaching the above-described layer B or the thermosetting film according to the embodiment of the present disclosure to the wiring pattern is not particularly limited, and a known laminating method or a hot pressing method can be used.

The heating means in the heating step is not particularly limited, and a known heating means such as a heater can be used.

The heating conditions are not particularly limited, and the heating can be carried out at a desired temperature and time in a known atmosphere.

From the viewpoint of dielectric loss tangent, laser processing suitability, and level difference followability, the heating temperature in the heating step is preferably 240° C. or lower, more preferably 120° C. or higher and 220° C. or lower, still more preferably 140° C. or higher and 200° C. or lower, and particularly preferably 150° C. or higher and 180° C. or lower.

From the viewpoint of laser processing suitability and level difference followability, a value obtained by subtracting a mass residual rate at 900° C. from a mass residual rate at 440° C. of the layer B or the thermosetting film after the heating step is preferably 40% or more, preferably 40% to 95%, and particularly preferably 45% to 90%.

In addition, the manufacturing method of a wiring board according to the embodiment of the present disclosure may include other known steps as necessary.

### EXAMPLES

Hereinafter, the present disclosure will be described in more detail with reference to examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

In addition, in the present examples, unless otherwise specified, “%” and “part” mean “% by mass” and “part by mass” respectively.

### Production Example

### Polymer or Polymer Particles

P1: aromatic polyester amide (liquid crystal polymer) produced by the production method described below

### Synthesis of Aromatic Polyester Amide P1

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature increases from a room temperature (23° C., the same applies hereinafter) to 140° C. over 60 minutes while stirring under a nitrogen gas flow, and refluxing is performed at 140° C. for three hours.

Next, the temperature increases from 150° C. to 300° C. over five hours while by-produced acetic acid and unreacted acetic anhydride are distilled and is maintained at 300° C. for 30 minutes. Thereafter, a content is taken out from the reactor and is cooled to the room temperature. An obtained solid is ground by a grinder, and powdered aromatic polyester amide A1a is obtained. A flow start temperature of aromatic polyester amide A1a is 193° C. Aromatic polyester amide A1a is fully aromatic polyester amide.

Aromatic polyester amide A1a is subjected to solid-state polymerization by increasing the temperature from the room temperature to 160° C. over two hours and 20 minutes, next increasing the temperature from 160° C. to 180° C. over three hours and 20 minutes, and maintaining the temperature at 180° C. for five hours under a nitrogen atmosphere, and then, is cooled. Next, aromatic polyester amide A1a is pulverized by a pulverizer, and powdered aromatic polyester amide A1b is obtained. A flow start temperature of aromatic polyester amide A1b is 220° C.

Aromatic polyester amide A1b is subjected to solid-state polymerization by increasing the temperature from the room temperature to 180° C. for one hour and 25 minutes, next increasing the temperature from 180° C. to 255° C. over six hours and 40 minutes, and maintaining the temperature at 255° C. for five hours under a nitrogen atmosphere, and then, is cooled, and powdered aromatic polyester amide P1 is obtained.

A flow start temperature of aromatic polyester amide P1 is 302° C. A melting point of aromatic polyester amide P1 is measured using a differential scanning calorimetry apparatus, and is 311° C. Solubility of aromatic polyester amide P1 with respect to N-methylpyrrolidone at 140° C. is equal to or greater than 1% by mass.

### Preparation of Liquid Crystal Polymer Particles PP-1

1034.99 g (5.5 mol) of 2-hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst are put in a reactor comprising a stirring device, a torque meter, a nitrogen gas introduction pipe, a thermometer, and a reflux condenser. Gas in the reactor is substituted with nitrogen gas, and then, acetic anhydride (1.08 molar equivalent with respect to a hydroxyl group) is further added. A temperature increases from a room temperature to 150° C. over 15 minutes while stirring under a nitrogen gas flow, and refluxing is performed at 150° C. for two hours.

Next, the temperature increases from 150° C. to 310° C. over five hours while by-produced acetic acid and unreacted acetic anhydride are distilled, and a polymerized substance is taken out and is cooled to the room temperature. An obtained polymerized substance increases in temperature from the room temperature to 295° C. over 14 hours, and is subjected to solid-state polymerization at 295° C. for one hour. After the solid-state polymerization, the temperature was lowered to room temperature over 5 hours, thereby obtaining liquid crystal polymer particles PP-1. The liquid crystal polymer particles PP-1 had a median diameter (D50) of 7 μm, a dielectric loss tangent of 0.0007 at 28 GHz, and a melting point of 334° C.

### Preparation of Liquid Crystal Polymer Particles PP-2

Spherical liquid crystal polymer particles were produced with reference to Production Example 1 described in WO2019/240153A. The median diameter (D50) was 10 μm, the dielectric loss tangent was 0.0021, and the melting point was 325° C.

### Synthesis of Allyl Group-Containing Polyphenylene Ether Resin T3

5.3 g of di-u-hydroxo-bis[(N,N,N′,N′-tetramethylethylenediamine) copper (II)] chloride (Cu/TMEDA) and 5.7 mL of tetramethylethylenediamine (TMEDA) were added to a 3 L two-neck eggplant flask and sufficiently dissolved, and oxygen was supplied at 10 ml/min. 15.1 g of o-cresol, 13.8 g of 2-allyl-6-methylphenol, and 85.5 g of 2,6-dimethylphenol as raw material phenols were dissolved in 1.5 L of toluene, and the solution was added dropwise to a flask and reacted at 40° C. for 6 hours with stirring at a rotation speed of 600 rpm. After completion of the reaction, the precipitate was reprecipitated with a mixed solution of 20 L of methanol and 22 mL of concentrated hydrochloric acid, and was taken out by filtration, and dried at 80° C. for 24 hours to obtain T3a as a polyphenylene ether, where Mn=10,000.

50 g of T3a, 2.25 g of 4-chloromethylstyrene as a modification compound, 3 g of tetrabutylammonium bromide as a phase-transfer catalyst, and 500 mL of toluene were added to a 1 L two-neck eggplant flask comprising a dropping funnel, and the mixture was heated and stirred at 75° C. 15 mL of an 8 M NaOH aqueous solution was added dropwise to the solution over 20 minutes. Thereafter, the mixture was further stirred at 75° C. for 5 hours. Next, the reaction solution was neutralized with hydrochloric acid, then reprecipitated in 5 L of methanol, and taken out by filtration, and washed three times with a mixed solution of methanol and water at a mass ratio of 80:20, and then dried at 80° C. for 24 hours to obtain an allyl group-containing polyphenylene ether resin T3.

### Synthesis of Vinyl Group-Containing Polyphenylene Ether Resin T4

1,1-bis(4-hydroxyphenyl)-3,3,5-trimethylcyclohexane (BisTMC) (12.4 g, 40.0 mmol), 4,4′-(1,3-dimethylbutylidene) bisphenol (BisP-MIBK) (2.7 g, 10.0 mmol), 1,1-bis(4-hydroxyphenyl)-nonane (BisP-DED) (3.3 g, 10.0 mmol), 4,6-dichloro-2-phenylpyrimidine (PhPym) (13.7 g, 61.1 mmol), and potassium carbonate (11.4 g, 82.5 mmol) were weighed into a four-neck separable flask comprising a stirring device, N-methyl-2-pyrrolidone (75 g) was added thereto, and the mixture was reacted at 130° C. for 6 hours under a nitrogen atmosphere. After completion of the reaction, N-methyl-2-pyrrolidone (368 g) was added for dilution, the salt was removed by filtration, and then this solution was added to methanol (9.1 kg). The precipitated solid was separated by filtration, washed with a small amount of methanol, and separated by filtration again to be recovered, and then dried at 120° C. under reduced pressure for 12 hours using a vacuum dryer to obtain a polymer T4a.

50 g of T4a, 2.25 g of 4-chloromethylstyrene as a modification compound, 3 g of tetrabutylammonium bromide as a phase-transfer catalyst, and 500 mL of toluene were added to a 1 L two-neck eggplant flask comprising a dropping funnel, and the mixture was heated and stirred at 75° C. 15 mL of an 8 M NaOH aqueous solution was added dropwise to the solution over 20 minutes. Thereafter, the mixture was further stirred at 75° C. for 5 hours. Next, the reaction solution was neutralized with hydrochloric acid, then reprecipitated in 5 L of methanol, and taken out by filtration, and washed three times with a mixed solution of methanol and water at a mass ratio of 80:20, and then dried at 80° C. for 24 hours to obtain a vinyl group-containing polyphenylene ether resin T4.

### Synthesis of Allyl Group-Containing Polyarylate Resin T7

NaOH (3.9 g) and distilled water (375 ml) were added and mixed in a 1 L three-neck eggplant flask, and then Na2S204 (0.05 g), 2,3,5-trimethylphenol (0.17 g), 2,2′-diallylbisphenol A (12.4 g), benzyltributylammonium chloride (0.06 g), and distilled water (100 ml) were added thereto. After ice-cooling to 0° C., a solution obtained by dissolving 4,4′-biphenyldicarboxylic acid chloride (11.4 g) in dichloromethane (500 ml) was added dropwise thereto, and the mixture was stirred at room temperature for 4 hours. After adding distilled water (240 ml) and acetic acid (3.4 ml), the aqueous layer was removed by liquid separation, distilled water (240 ml) was further added, and the aqueous layer was removed by liquid separation. The obtained organic layer was reprecipitated in methanol (2 L), collected by filtration, and dried (50° C.) to obtain an allyl group-containing polyarylate resin T7.

Details of the components used in each layer are shown below.

### Layer A

P1: aromatic polyester amide P1 (produced by the above-described method)
PP-1: liquid crystal polymer particles PP-1 (produced by the above-described method)
PP-2: liquid crystal polymer particles PP-2 (produced by the above-described method)
P6: S202A, manufactured by Asahi Kasei Corporation, polyphenylene ether resin (Layer B)

### Thermoplastic Resin

P2: TAFTEC M1913, manufactured by Asahi Kasei Corporation, a hydrogenated styrene-ethylene-butylene-styrene block copolymer.
P3: TUFPRENE 912, manufactured by Asahi Kasei Corporation, styrene-butadiene-styrene block copolymer
P4: EPOFRIEND AT501, manufactured by Daicel Corporation, styrene-butadiene-styrene block copolymer

### Thermosetting Resin

T1: MIR-3000, manufactured by Nippon Kayaku Co., Ltd., bismaleimide resin
T2: BMI-70, manufactured by KIEI KASEI Co., Ltd., bismaleimide resin
T3: allyl group-containing polyphenylene ether resin T3 (produced by the above-described method)
T4: vinyl group-containing polyphenylene ether resin T4 (produced by the above-described method)
T5: HP-4032D, manufactured by DIC Corporation, epoxy resin
T6: jER YX8800, manufactured by Mitsubishi Chemical Corporation, condensed polyfunctional epoxy resin
T7: polyarylate resin T7 containing an allyl group (produced by the above-described method)

### Polymerization Initiator (Initiator) and Catalyst

V1: cumene hydroperoxide, thermal radical initiator
V2: 2E4MZ, manufactured by Shikoku Chemicals Corporation, imidazole-based catalyst

### Additive Resin and Particles

F1: silica particles, SC2050-MB, manufactured by Admatechs Co., Ltd., particle diameter 0.5 μm
F2: polytetrafluoroethylene (PTFE) resin particles, TF-9205, manufactured by 3M Company

PP-1: liquid crystal polymer particles PP-1 (produced by the above-described method)
P5: polyimide PIAD-200, manufactured by Arakawa Chemical Industries, Ltd. (Examples 1 to 24 and Comparative Example 1)

### Preparation of Coating Liquid for Undercoat Layer

8 parts of aromatic polyester amide P1 was added to 92 parts of N-methylpyrrolidone, and the mixture was stirred at 140° C. for 4 hours under a nitrogen atmosphere to obtain an aromatic polyester amide solution P1 (concentration of solid contents: 8% by mass).

An aminophenol type epoxy resin (“jER630” manufactured by Mitsubishi Chemical Corporation, 0.04 parts by mass) was mixed with the aromatic polyester amide solution P1 (10.0 parts by mass) to prepare an undercoat layer coating liquid.

### Preparation of Coating Liquid for Layer A

The polymer and the polymer particles shown in Table 1 were mixed in the ratio of parts by mass shown in Table 1, N-methylpyrrolidone was added thereto to adjust the concentration of solid contents to be 25% by mass, and a coating liquid for a layer A was obtained.

### Preparation of Coating Liquid for Layer B

The thermoplastic resin, the thermosetting resin, the initiator/catalyst, and the additive shown in Table 1 were mixed together in the mass ratio shown in Table 1, toluene was added thereto to adjust the concentration of solid contents to 25% by mass, and a coating liquid for a layer B was obtained.

### Production of Base Material With Wiring Pattern

A copper foil (product name “CF-T9DA-SV-18”, average thickness of 18 μm, manufactured by Fukuda Metal Foil & Powder Co., Ltd.) and a liquid crystal polymer film (product name “CTQ-50”, average thickness of 50 μm, manufactured by Kuraray Co., Ltd.) as a base material were produced. The copper foil, the base material, and the copper foil were laminated in this order such that the treated surface of the copper foil was in contact with the base material. A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a thermal compression machine (product name “MP-SNL”, manufactured by Toyo Seiki Seisaku-sho, Ltd.), the obtained double-sided copper-clad laminated plate precursor was thermally compression-bonded for 10 minutes under conditions of 300° C. and 4.5 MPa to prepare a double-sided copper-clad laminated plate.

Each of the copper foils on both surfaces of the above-described double-sided copper-clad laminated plate was etched to perform patterning, and a base material with wiring patterns including a ground line and three pairs of signal lines on both sides of the base material was produced. A length of the signal line was 50 mm, and a width of the signal line was set such that characteristic impedance was 50 Ω.

### Method of Producing Single-Layer Film of Layer B

The coating liquid for the layer B was applied onto the easy-peel surface of the release PET film using an applicator, and the coating liquid was dried by blowing air at 90° C. for 1 hour. Then, the PET film was peeled off to obtain a single-layer film of the layer B.

### Method of Producing Layer A Film

The obtained undercoat layer coating liquid was applied onto a treatment surface of a copper foil (manufactured by FUKUDA METAL FOIL & POWER CO., LTD., CF-T4X-SV-18, thickness: 18 μm, surface roughness Rz of a surface to be attached (treatment surface): 0.85 μm) using an applicator, and blast-dried at 150° C. for 1 hour. The film thickness of the undercoat layer after drying was 3 μm. The coating liquid for a layer A was applied onto the obtained undercoat layer using an applicator, and the coating liquid was blast-dried at 50° C. for 3 hours. Thereafter, an annealing treatment was performed at 300° C. for 3 hours under nitrogen. The copper foil of the obtained film was dissolved in a ferric chloride aqueous solution to obtain a layer A film.

### Method of Producing Single-Sided Copper-Clad Laminated Film

The obtained undercoat layer coating liquid was applied onto a treatment surface of a copper foil (manufactured by FUKUDA METAL FOIL & POWER CO., LTD., CF-T4X-SV-18, thickness: 18 μm, surface roughness Rz of a surface to be attached (treatment surface): 0.85 μm) using an applicator, and blast-dried at 150° C. for 1 hour. The film thickness of the undercoat layer after drying was 3 μm. The coating liquid for a layer A was applied onto the obtained undercoat layer using an applicator, and the coating liquid was blast-dried at 50° C. for 3 hours. Thereafter, an annealing treatment was performed at 300° C. for 3 hours under nitrogen. The film thickness of the layer A was as shown in Table 1. A coating liquid for a layer B was further applied onto the obtained layer A using an applicator, and the coating liquid was dried by blowing air at 90° C. for 1 hour to obtain a polymer film having a copper layer (a single-sided copper-clad laminated film).

### Method A of Producing Laminate With Wiring Pattern

The base material with a wiring pattern produced above was overlaid on the layer B side of the obtained single-sided copper-clad laminated film, and subjected to a heat press for 1 hour under the conditions of 160° C. and 4 MPa to obtain a laminate with a wiring pattern.

In the obtained laminate, the wiring pattern (ground line and signal line) was embedded, and the thickness of the wiring pattern was 18 μm.

### Method B of Producing Laminate With Wiring Pattern

The obtained undercoat layer coating liquid was applied onto a treatment surface of a copper foil (manufactured by FUKUDA METAL FOIL & POWER CO., LTD., CF-T4X-SV-18, thickness: 18 μm, surface roughness Rz of a surface to be attached (treatment surface): 0.85 μm) using an applicator, and blast-dried at 150° C. for 1 hour. The film thickness of the undercoat layer after drying was 3 μm. The coating liquid for a layer A was applied onto the obtained undercoat layer using an applicator, and the coating liquid was blast-dried at 50° C. for 3 hours. Thereafter, an annealing treatment was performed at 300° C. for 3 hours under nitrogen. The film thickness of the layer A was as shown in Table 1. Further, the single-layer film of the layer B prepared above was placed on the obtained layer A, and the base material with a wiring pattern prepared above was further overlaid on the layer B, and the laminate with a wiring pattern was obtained by performing a heat press for 1 hour under the conditions of 160° C. and 4 MPa.

In the obtained laminate, the wiring pattern (ground line and signal line) was embedded, and the thickness of the wiring pattern was 18 μm.

### Evaluation

The produced films were evaluated by the following methods, and the results are shown in Table 1.

### Measurement Method

### Elastic Modulus at 160° C.

### Single-Sided Copper-Clad Laminated Film

The elastic modulus of the layer B of the single-sided copper-clad laminated film was measured as an indentation elastic modulus using a nanoindentation method. The indentation elastic modulus was measured by using a microhardness tester (product name “DUH-W201”, manufactured by Shimadzu Corporation) to apply a load at a loading rate of 0.28 mN/sec with a Vickers indenter at 160° C., holding a maximum load of 10 mN for 10 seconds, and then unloading at a loading rate of 0.28 mN/sec.

### Elastic Modulus of Layer B Single-Layer Film at 160° C.

Using a rheometer RS6000 manufactured by EIHOH Corporation, the elastic modulus of the layer B before curing was measured under the following conditions. The samples were overlaid so that the thickness was about 0.1 mm. The elastic modulus at a point in time of 5 minutes after the start of measurement was read, and the average value of the n=3 measurements was calculated.
Force control mode: (Fn=2N)
Frequency: 1 Hz
Strain: 0.2%
Temperature: 160° C. constant
Measurement time: 15 minutes

### Mass Residual Rate

The layer A or the layer B was cut from the film, 5 mg thereof was added to a platinum pan, and the measurement was performed at a temperature rising rate of 10° C./min and a measurement temperature of 25° C. to 900° C. using a differential thermal balance (TG-DTA) (TG-8120 manufactured by Rigaku Corporation). The mass residual rate was set to the following value.

Mass residual rate (%)=mass residual rate (%) at 440° C.−mass residual rate (%) at 900° C.

### Dielectric Loss Tangent

The dielectric loss tangent was measured by a resonance perturbation method at a frequency of 28 GHz. A 28 GHz cavity resonator (CP531 manufactured by KANTO Electronic Application and Development Inc.) is connected to a network analyzer (“E8363B” manufactured by Agilent Technology Co., Ltd.), the test piece is inserted into the cavity resonator, and the dielectric loss tangent of the film is measured from change in resonance frequency before and after insertion for 96 hours under an environment of a temperature of 25° C. and humidity of 60% RH.

The dielectric loss tangent of the layer A was measured using the layer A film produced above.

The dielectric loss tangent of the layer B was measured using the single-layer film of the layer B produced as described above.

The dielectric loss tangent of the laminate was obtained by weighted averaging the dielectric loss tangents and the film thicknesses of the layer A and the layer B.

### Level Difference Followability (Wiring Line Followability)

The laminate with a wiring pattern was cut in a thickness direction with a microtome, and the cross section was observed with an optical microscope. The length L1 of the gap generated in the in-plane direction between the layer B and the wiring pattern was measured. The average value of the results at 10 points was calculated.
A: L1 is less than 2 μm.
B: L1 is 2 μm or more and less than 4 μm.
C: L1 is 4 μm or more.

### Laser Processing Suitability

### (1) Production of Sample

A treatment surface of a copper foil (product name “CF-T9DA-SV-18”, average thickness: 18 μm, manufactured by FUKUDA METAL FOIL & POWER CO., LTD.) was overlaid on the layer B surface side of the produced single-sided copper-clad laminated film. A laminating treatment was performed for 60 minutes under the conditions of 160° C. and 4 MPa using a laminator (product name “Vacuum laminator V-130”, manufactured by NIKKO MATERIALS CO., LTD.) to obtain a double-sided copper-clad laminated plate.

### (2) Measuring Method

Through-hole via holes were processed from the single-sided copper-clad laminated plate side of the double-sided copper-clad laminated plate using a UV-YAG laser Model 5330 manufactured by ESI. The cross section of the via portion was observed with an optical microscope, and the length L2 of peeling of the layer A and the layer B (that is, the maximum length of the recess formed in the cross section of the cut portion in a horizontal direction) was measured. Evaluation criteria are as follows.
A: L2 is less than 6 μm.
B: L2 is 6 μm or more and less than 15 μm.
C: L2 is 15 μm or more

TABLE 1

| | Film configuration | | | | | | | | | | | |
|---|---|---|---|---|---|---|---|---|---|---|---|---|
| | | | | | | | | Layer B | | | | |
| | | Layer A | | | | | | Configuration | | | | |
| | | Configuration | | | | | | Thermoplastic | | Thermosetting | | |
| | | Polymer | | Polymer particles | | | | resin | | resin | | |
| | Manufac- | | Addition | | Addition | | Dielec- | | Addition | | Addition | |
| | turing | | amount | | amount | Thick- | tric | | amount | | amount | Initiator/ |
| | method of | | (part by | | (part by | ness | loss | | (part by | | (part by | catalyst |
| | laminate | Type | mass) | Type | mass) | (μm) | tangent | Type | mass) | Type | mass) | Type |
| Example 1 | A | P1 | 30 | PP-1 | 70 | 27 | 0.002 | P2 | 82 | T1 | 17 | V2 |
| Example 2 | A | P1 | 30 | PP-1 | 70 | 27 | 0.002 | P2 | 75 | T1 | 23 | V2 |
| Example 3 | A | P1 | 30 | PP-1 | 70 | 27 | 0.002 | P2 | 66 | T1 | 33 | V2 |
| Example 4 | A | P1 | 30 | PP-1 | 70 | 27 | 0.002 | P2 | 76 | T1 | 23 | V1 |
| Example 5 | A | P1 | 30 | PP-1 | 70 | 27 | 0.002 | P2 | 75 | T2 | 23 | V1 |
| Example 6 | A | P1 | 30 | PP-1 | 70 | 27 | 0.002 | P2 | 75 | T3 | 23 | V1 |
| Example 7 | A | P1 | 30 | PP-1 | 70 | 27 | 0.002 | P2 | 75 | T4 | 23 | V1 |
| Example 8 | A | P1 | 30 | PP-1 | 70 | 27 | 0.002 | P2 | 76 | T5 | 23 | V2 |
| Example 9 | A | P1 | 30 | PP-1 | 70 | 27 | 0.002 | P3 | 75 | T1 | 23 | V1 |
| Example 10 | A | P1 | 30 | PP-1 | 70 | 27 | 0.002 | P3 | 75 | T3 | 23 | V1 |
| Example 11 | A | P1 | 30 | PP-1 | 70 | 27 | 0.002 | P4 | 75 | T1 | 23 | V1 |
| Example 12 | A | P1 | 30 | PP-1 | 70 | 27 | 0.002 | P4 | 75 | T3 | 23 | V1 |
| Example 13 | A | P1 | 30 | PP-1 | 70 | 27 | 0.002 | P2 | 53 | T1 | 16 | V1 |
| Example 14 | A | P1 | 30 | PP-1 | 70 | 27 | 0.002 | P2 | 53 | T1 | 16 | V1 |
| Example 15 | A | P1 | 30 | PP-1 | 70 | 27 | 0.002 | P2 | 53 | T1 | 16 | V1 |
| Example 16 | A | P1 | 30 | PP-1 | 70 | 27 | 0.002 | P2 | 53 | T1 | 16 | V1 |
| Example 17 | A | P1 | 30 | PP-1 | 70 | 27 | 0.002 | P2 | 75 | T7 | 23 | V1 |
| Example 18 | A | P1 | 40 | PP-1 | 60 | 27 | 0.003 | P2 | 75 | T1 | 23 | V2 |
| Example 19 | A | P6 | 100 | — | — | 27 | 0.003 | P2 | 75 | T1 | 23 | V2 |
| Example 20 | B | P1 | 30 | PP-1 | 70 | 27 | 0.002 | P2 | 75 | T1 | 23 | V2 |
| Example 21 | B | P1 | 30 | PP-1 | 70 | 27 | 0.002 | P2 | 75 | T3 | 23 | V1 |
| Example 22 | B | P1 | 30 | PP-1 | 70 | 27 | 0.002 | P2 | 53 | T1 | 16 | V1 |
| Example 23 | A | P1 | 30 | PP-1 | 70 | 20 | 0.002 | P2 | 75 | T1 | 23 | V2 |
| Example 24 | A | P1 | 30 | PP-2 | 70 | 27 | 0.0035 | P2 | 75 | T1 | 23 | V2 |
| Comparative | — | P1 | 30 | PP-1 | 70 | 27 | 0.002 | P2 | 94 | T6 | 5 | V2 |
| Example 1 | | | | | | | | | | | | |

| | Film configuration | | | | | | | | | |
|---|---|---|---|---|---|---|---|---|---|---|
| | Layer B | | | | | | | | | |
| | Configuration | | | | | | | | | |
| | Initiator/ | | | | | | | Dielec- | | |
| | catalyst | Additive | | | | | Elastic | tric | Evaluation result | |
| | Addition | | Addition | | Dielec- | Mass | modulus | loss | Level | |
| | amount | | amount | Thick- | tric | residual | at 160° C. | tangent | difference | Laser |
| | (part by | | (part by | ness | loss | rate | before | of | follow- | processing |
| | mass) | Type | mass) | (μm) | tangent | (%) | curing | laminate | ability | suitability |
| Example 1 | 1 | — | — | 25 | 0.002 | 41 | 0.09 | 0.002 | A | A |
| Example 2 | 1 | — | — | 25 | 0.002 | 52 | 0.09 | 0.002 | A | A |
| Example 3 | 1 | — | — | 25 | 0.002 | 55 | 0.09 | 0.002 | A | A |
| Example 4 | 2 | — | — | 25 | 0.002 | 48 | 0.09 | 0.002 | A | A |
| Example 5 | 2 | — | — | 25 | 0.002 | 49 | 0.15 | 0.002 | A | A |
| Example 6 | 2 | — | — | 25 | 0.002 | 54 | 0.20 | 0.002 | A | A |
| Example 7 | 2 | — | — | 25 | 0.002 | 54 | 0.20 | 0.002 | A | A |
| Example 8 | 1 | — | — | 25 | 0.003 | 40 | 0.49 | 0.0025 | B | B |
| Example 9 | 2 | — | — | 25 | 0.003 | 71 | 0.04 | 0.0025 | A | A |
| Example 10 | 2 | — | — | 25 | 0.003 | 71 | 0.08 | 0.0025 | A | A |
| Example 11 | 2 | — | — | 25 | 0.003 | 56 | 0.04 | 0.0025 | A | A |
| Example 12 | 2 | — | — | 25 | 0.003 | 56 | 0.08 | 0.0025 | A | A |
| Example 13 | 2 | F1 | 30 | 25 | 0.002 | 54 | 0.26 | 0.002 | A | A |
| Example 14 | 2 | F2 | 30 | 25 | 0.002 | 54 | 0.15 | 0.002 | A | A |
| Example 15 | 2 | PP-A | 30 | 25 | 0.002 | 71 | 0.35 | 0.002 | A | A |
| Example 16 | 2 | P5 | 30 | 25 | 0.002 | 68 | 0.09 | 0.002 | A | A |
| Example 17 | 2 | — | — | 25 | 0.002 | 54 | 0.20 | 0.002 | A | A |
| Example 18 | 1 | — | — | 25 | 0.002 | 52 | 0.09 | 0.0025 | A | A |
| Example 19 | 1 | — | — | 25 | 0.002 | 52 | 0.09 | 0.0025 | A | A |
| Example 20 | 1 | — | — | 25 | 0.002 | 52 | 0.09 | 0.002 | A | A |
| Example 21 | 2 | — | — | 25 | 0.002 | 54 | 0.20 | 0.002 | A | A |
| Example 22 | 2 | F1 | 30 | 25 | 0.002 | 54 | 0.26 | 0.002 | A | A |
| Example 23 | 1 | — | — | 30 | 0.002 | 52 | 0.09 | 0.002 | A | A |
| Example 24 | 1 | — | — | 25 | 0.002 | 52 | 0.09 | 0.0028 | A | A |
| Comparative | 1 | — | — | 25 | 0.0025 | 20 | 0.55 | 0.0023 | C | C |
| Example 1 | | | | | | | | | | |

From the results shown in Table 1, the films, laminates, or thermosetting films of Examples 1 to 24 were more excellent in the level difference followability and the laser processing suitability than the film of Comparative Example 1.

The disclosure of JP2022-138486 filed on Aug. 31, 2022 is incorporated in the present specification by reference in its entirety.

All documents, patent applications, and technical standards described in the present specification are herein incorporated by reference to the same extent that individual documents, patent applications, and technical standards have been specifically and individually indicated to be incorporated by reference, respectively.

What is claimed is:

1. A laminate comprising:
a layer A;
a layer B on at least one surface of the layer A; and
a conductive pattern in contact with at least a part of the layer B,
wherein the laminate has a dielectric loss tangent of 0.01 or less at 28 GHz, and
a value obtained by subtracting a mass residual rate of the layer B at 900° C. from a mass residual rate of the layer B at 440° C. is 40% by mass or more.

2. The laminate according to claim 1,
wherein the layer B comprises a resin having at least one group selected from the group consisting of a maleimide group, an allyl group, and a vinyl group.

3. The laminate according to claim 1,
wherein the layer B comprises a thermoplastic elastomer.

4. The laminate according to claim 1,
wherein the layer B comprises an inorganic filler.

5. The laminate according to claim 1,
wherein the layer A comprises a liquid crystal polymer.

6. The laminate according to claim 1,
wherein the layer A comprises an aromatic polyester amide.

7. A film comprising:
a layer A; and
a layer B on at least one surface of the layer A,
wherein the film has a dielectric loss tangent of 0.01 or less at 28 GHz,
an elastic modulus of the layer B of 0.5 MPa or less at 160° C., and
the layer B comprises a thermosetting resin.

8. The film according to claim 7,
wherein the thermosetting resin has at least one group selected from the group consisting of a maleimide group, an allyl group, and a vinyl group.

9. The film according to claim 7,
wherein the layer B further comprises a thermoplastic elastomer.

10. The film according to claim 7,
wherein the layer B comprises an inorganic filler.

11. The film according to claim 7,
wherein the layer A comprises a liquid crystal polymer.

12. The film according to claim 7,
wherein the layer A comprises aromatic polyester amide.

13. A method of manufacturing a wiring board, the method comprising:
overlaying the film according to claim 7 on a wiring pattern of a base material with a wiring pattern from a side of the layer B; and
heating the base material with a wiring pattern and the film in a state of being overlaid to obtain a wiring board.

14. The method according to claim 13,
wherein a value obtained by subtracting a mass residual rate of the layer B at 900° C. from a mass residual rate of the layer B at 440° C. after the heating is 40% or more.

15. A thermosetting film comprising:
a thermosetting compound; and
a thermoplastic elastomer,
wherein the thermosetting compound has at least one group selected from the group consisting of a maleimide group, an allyl group, and a vinyl group.

16. The thermosetting film according to claim 15,
wherein the thermosetting film has an elastic modulus of 0.5 MPa or less at 160° C.

17. The thermosetting film according to claim 15,
wherein the thermosetting film has a dielectric loss tangent of 0.01 or less at 28 GHz.

18. The thermosetting film according to claim 15, further comprising:
at least one selected from the group consisting of a polyimide, a liquid crystal polymer, a fluorine-based polymer, and an inorganic filler.

19. The thermosetting film according to claim 15, further comprising:
an aromatic polyester amide.

20. A method of manufacturing a wiring board, the method comprising:
overlaying the thermosetting film according to claim 15 on a wiring pattern of a base material with a wiring pattern; and
heating the base material with the wiring pattern and the thermosetting film in a state of being overlaid to obtain a wiring board.

21. The method according to claim 20,
wherein a value obtained by subtracting a mass residual rate of the thermosetting film at 900° C. from a mass residual rate of the thermosetting film at 440° C. after the heating step is 40% or more.
